(19) United States
(12) Patent Application Publication
(10) Pub. No.: US 2025/0337363 A1
(43) Pub. Date: Oct. 30, 2025

(54) ELECTRONIC DEVICE INCLUDING POWER SUPPLY FOR POWER AMPLIFIER

(71) Applicant: Samsung Electronics Co., Ltd., Suwon-si (KR)

(72) Inventors: Yohan MOON, Suwon-si (KR); Hyunsang KANG, Suwon-si (KR); Hyoseok NA, Suwon-si (KR); Dongil YANG, Suwon-si (KR)

(21) Appl. No.: 19/188,783

(22) Filed: Apr. 24, 2025

Related U.S. Application Data
(63) Continuation of application No. PCT/KR2025/005562, filed on Apr. 24, 2025.

(30) Foreign Application Priority Data
Apr. 24, 2024 (KR) 10-2024-0054574
Jun. 25, 2024 (KR) 10-2024-0083057

(51) Int. Cl. H03F 1/02; H03F 3/24; H03F 3/72

(52) U.S. Cl. CPC H03F 1/0227; H03F 3/245; H03F 3/72; H03F 2200/102; H03F 2200/105; H03F 2200/294; H03F 2200/451; H03F 2203/7209

(57) ABSTRACT

Wireless communication circuitry for use in an electronic device may comprise: a power amplifier configured to amplify (RF) signals in a first frequency band of a first radio access technology (RAT) in a first communication mode and to amplify RF signals in a second frequency band of a second RAT in a second communication mode and a switch including a first input node configured to be connectable to receive an envelope tracking power supply signal, a second input node configured to be connectable to receive an average power tracking (APT) power supply signal, and an output node connected to the PA. The switch may be configured to switchably connect one of the first input node and the second input node to the output node in response to a switching control signal.

### CROSS-REFERENCE TO RELATED APPLICATIONS

This application is a continuation of International Application No. PCT/KR2025/005562 designating the United States, filed on Apr. 24, 2025, in the Korean Intellectual Property Receiving Office and claiming priority to Korean Patent Application Nos. 10-2024-0054574, filed on Apr. 24, 2024, and 10-2024-0083057, filed on Jun. 25, 2024, in the Korean Intellectual Property Office, the disclosures of each of which are incorporated by reference herein in their entireties.

### BACKGROUND

### Field

The disclosure relates to an electronic device including a power supply for a power amplifier (PA).

### Description of Related Art

Advancing information communication technologies and semiconductor technologies accelerate the spread and use of various electronic devices. Electronic devices are being developed to be carried around by users and to communicate with other devices using wireless communication technology.

Wireless communication electronic device may refer to a device performing a particular function according to its equipped program, such as a mobile communication terminal, an electronic scheduler, a portable multimedia player, a tablet PC, a video/sound device, a desktop/laptop computer, a home appliance, or a navigation for automobile. These electronic devices may be configured to transmit or receive wireless signals over a designated frequency band. Some electronic devices have been downsized to be conveniently carried by users.

Portable electronic devices are required to support various frequency bands, e.g., frequency ranges of 2nd generation (2G) communication technology, 3rd generation (3rd) communication technology, 4th generation (4G) communication technology (e.g., long term evolution (LTE)), and/or 5th generation (5th) communication technology (e.g., new radio (NR)). Electronic devices supporting 5G communication technology may communicate using not only NR standalone (SA) but also evolved universal mobile telecommunications system terrestrial radio access (E-UTRA) NR dual-connectivity (EN-DC). The electronic device may include one or more power amplifiers (PAs) in a radio frequency (RF) circuit for supporting dual connectivity (DC) and one or more power supplies for the power amplifiers.

The above-described information may be provided as related art for the purpose of helping understanding of the disclosure. No assertion or determination is made as to whether any of the foregoing is applicable as background art in relation to the disclosure.

### SUMMARY

Embodiments of the disclosure may provide a power supply for a power amplifier and an electronic device including the power supply.

Embodiments of the disclosure may provide an electronic device to selectively supply average power tracking (APT) power and ET power to a power amplifier using a power supply switch.

Wireless communication circuitry used in an electronic device according to an example embodiment of the disclosure may comprise: a power amplifier (PA) configured to amplify radio frequency (RF) signals in a first frequency band of a first radio access technology (RAT) in a first communication mode and amplify RF signals in a second frequency band of a second RAT in a second communication mode; a switch including a first input node configured to be connectable to receive an envelope tracking (ET) power supply signal, a second input node configured to be connectable to receive an average power tracking (APT) power supply signal, and an output node connected to the PA, and configured to switchably connect one of the first input node and the second input node to the output node in response to a switching control signal.

An electronic device according to an example embodiment of the disclosure may comprise: a first power supply configured to generate a first electrical power by an envelope tracking (ET) power supply scheme and a second electrical power by an average power tracking (APT) power supply scheme; a second power supply configured to generate a third electrical power by the ET power supply scheme and a fourth electrical power by the APT power supply scheme; a first power amplifier (PA) configured to amplify RF signals in a first frequency band of a first radio access technology (RAT) and a second frequency band of a second RAT; a first switch including a first input node configured to be connectable to receive the first electrical power, a second input node configured to be connectable to receive the fourth electrical power, and a first output node connected to the first PA, wherein first switch may be configured to switchably connect one of the first input node and the second input node to the first output node, in response to a first switching control signal for selecting, based on a communication mode of the electronic device, one of the first electrical power and the fourth electrical power and providing the selected one to the first PA via the first output node.

An electronic device according to an example embodiment of the disclosure may comprise: a first envelope tracking (ET) modulator configured to selectively provide a first envelope tracking power via a first power line, and/or a first average power tracking (APT) power via a second power line; a second envelope tracking modulator configured to selectively supply a second ET power via a third power line, and/or a second APT power via a fourth power line; a first amplifier configured to amplify a first transmission signal selected from among a first signal corresponding to a first wireless communication scheme, a second signal corresponding to a second wireless communication scheme, and a third signal corresponding to a third wireless communication scheme; a second amplifier configured to amplify a second transmission signal selected from among a fourth signal corresponding to the first wireless communication scheme, a fifth signal corresponding to the second wireless communication scheme, and a sixth signal corresponding to the third wireless communication scheme, wherein the fourth signal may correspond to a higher frequency band than the first signal, the fifth signal may correspond to a higher frequency band than the second signal, and the sixth signal may correspond to a higher frequency band than the third signal; a first switch configured to connect the first amplifier to the first envelope tracking modulator or the second envelope tracking modulator; and a second switch configured to connect the second amplifier to the first envelope tracking modulator or the second envelope tracking modulator.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a diagram illustrating an example electronic device in a network environment according to various embodiments;

FIGS. 2A and 2B are block diagrams illustrating example configurations of an electronic device for supporting legacy communication and 5G communication according to various embodiments;

FIGS. 3A and 3B are diagrams illustrating example connection with a network according to various embodiments;

FIG. 4 is a block diagram illustrating an example configuration of a power supply for power amplification according to various embodiments;

FIG. 5 is a diagram illustrating an example power supply structure including three power supplies according to various embodiments;

FIG. 6 is a diagram illustrating an example power supply structure including two power supplies according to various embodiments;

FIG. 7 is a diagram illustrating an example power supply structure including one power supply module according to various embodiments;

FIG. 8 is a diagram illustrating an example structure of an ET modulator according to various embodiments;

FIGS. 9A, 9B, 9C, 9D, and 9E are diagrams illustrating example structures of PA modules according various embodiments;

FIG. 10 is a diagram illustrating an example power supply structure including switches for power supply according to various embodiments;

FIG. 11 is a diagram illustrating an example power supply structure including two power supplies according to various embodiments;

FIG. 12 is a diagram illustrating an example power supply structure including one power supply module according to various embodiments;

FIGS. 13A and 13B are diagrams illustrating example structures of PA modules using a switch for power supply according to various embodiments;

FIG. 14 is a flowchart illustrating example operations for generating a switching control signal for selecting power for a power amplifier according to various embodiments;

FIG. 15 is a diagram illustrating an example power supply structure including a 3-way switch according to various embodiments; and

FIG. 16 is a diagram illustrating an example structure of a PA module using a 3-way switch according to various embodiments.

### DETAILED DESCRIPTION

The terms as used herein are provided merely to describe various embodiments thereof, but not to limit the scope of other embodiments of the disclosure. It is to be understood that the singular forms “a,” “an,” and “the” include plural references unless the context clearly dictates otherwise. The terms including technical and scientific terms used herein have the same meaning as commonly understood by one of ordinary skill in the art to which the various embodiments of the disclosure belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein. In some cases, the terms defined herein may be interpreted to exclude embodiments of the disclosure.

Methods described below in connection with an embodiment of the disclosure are based on hardware. However, embodiments of the disclosure may encompass technology using both hardware and software and thus does not exclude software-based methods.

As used in the following description, the terms related to multiple connectivity (e.g., dual-connectivity (DC), multi-radio access technology (RAT) (MR-DC), cell group, master cell group (MCG), secondary cell group (SCG)), the terms denoting signals (e.g., reference signal, system information, control signal, magnet, or data), the terms denoting network entities (e.g., communication node, radio node, radio unit, network node, master node (MN), secondary node (SN), transmission/reception point (TRP), digital unit (DU), radio (unit), or massive MIMO unit (MMU)) are used for convenience of description. The disclosure is not limited to the terms, and other terms equivalent in technical concept may also be used.

As used herein, to determine whether a specific condition is satisfied or fulfilled, when A is more than, or exceeds, B, A may also be not less than B or A may be equal to or more than B and, when A is less than B, A may also be not more than B or A may be equal to or less than B. The expressions “not less than,” “not more than,” and “not less than and less than” may be replaced with “more than,” “less than,” and “more than and not more than,” respectively.

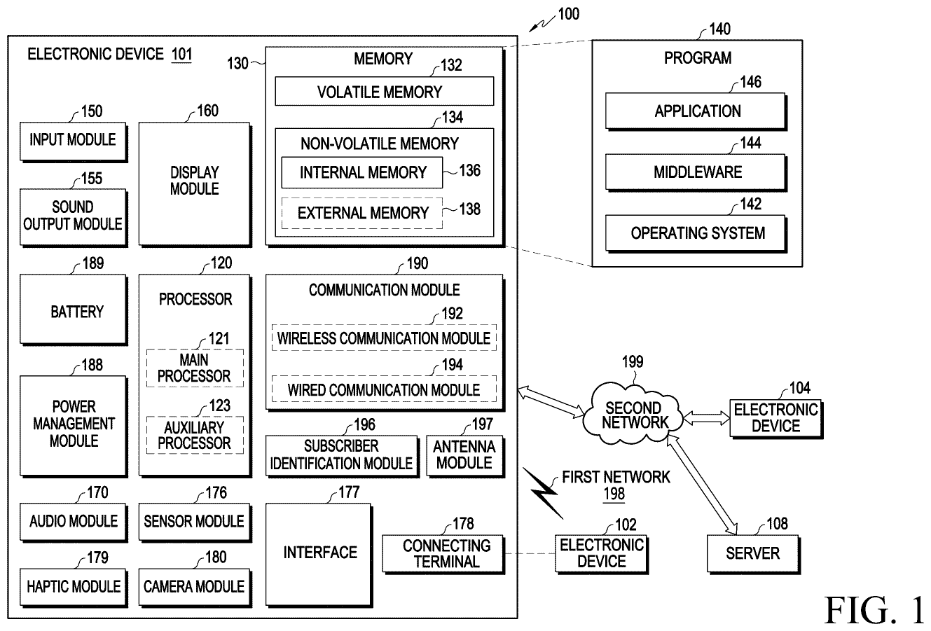

FIG. 1 is a diagram illustrating an example electronic device 101 in a network environment 100 according to various embodiments.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., transceiver (radio frequency integrated circuit)) than the radiator may be further formed as part of the antenna module 197.

According to various embodiments, the antenna module 197 may form a mmWave antenna module. According to an embodiment, the mmWave antenna module may include a printed circuit board, a transceiver disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

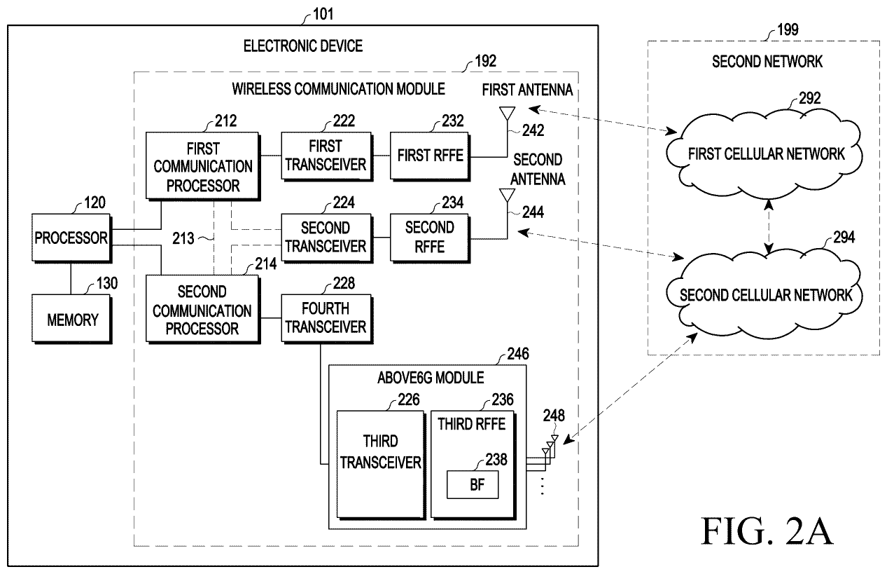

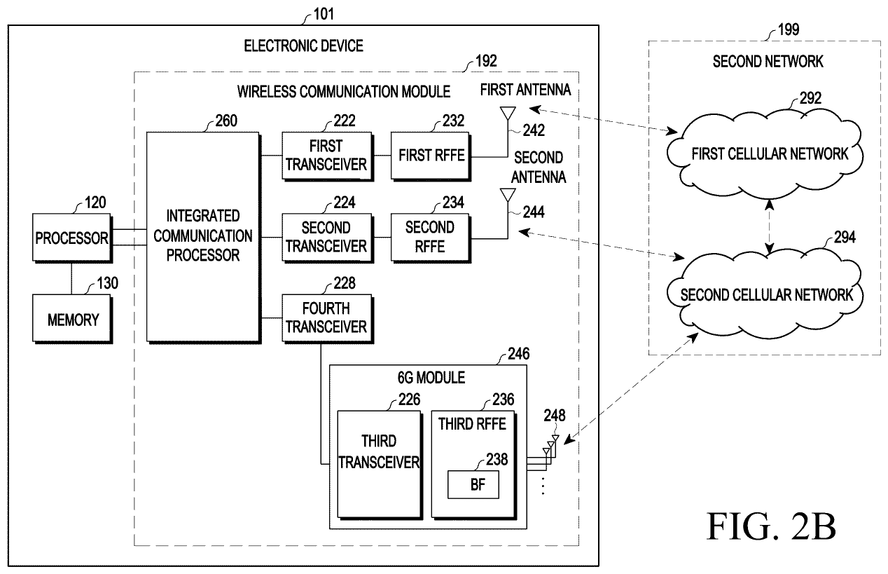

FIGS. 2A and 2B are block diagrams illustrating example configurations of an electronic device for supporting legacy communication and 5G communication according to various embodiments.

Referring to FIG. 2A, a wireless communication module 192 of an electronic device 101 may include a first communication processor (CP) (e.g., including processing circuitry) 212, a second communication processor (e.g., including processing circuitry) 222, a second transceiver 224, a third transceiver 226, a fourth transceiver 228, a first radio frequency front end (RFFE) 232, a second RFFE 234, a first antenna 242, a second antenna 244, an Above6G module 246, and an antenna array (e.g., including at least one antenna) 248. The Above6G module 246 may include a third transceiver 226 and a third RFFE 236. In an embodiment, at least one of the first RFFE 232, the second RFFE 234, or the third RFFE 236 may include at least one power amplifier (PA) for amplifying a transmitted RF signal in a designated RF band, and at least one low noise amplifier (LNA) for amplifying a received RF signal.

The second network 199 may include a first cellular network 292 and a second cellular network 294. According to an embodiment, the electronic device 101 may further include at least one component among the components of FIG. 1, and the second network 199 may further include at least one other network. According to an embodiment, at least one of the first communication processor 212, the second communication processor 214, the first transceiver 222, the second transceiver 224, the third transceiver 226, the fourth transceiver 228, the first RFFE 232, the second RFFE 234, or the third RFFE 236 may be at least a portion of the wireless communication module 192, or may be included in a module other than the wireless communication module 192. In an embodiment, the fourth transceiver 228 may be omitted or included as a portion of the Above6G module 246.

The first communication processor 212 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner.

At least one processor may execute program instructions to achieve or perform various functions, and establish a communication channel of a band that is to be used for wireless communication with the first cellular network 292 or may support legacy communication via the established communication channel. According to an embodiment, the first cellular network may be a legacy network that includes at least one of a 2G, 3G, 4G, or LTE network.

The second communication processor 214 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner.

At least one processor may execute program instructions to achieve or perform various functions, and establish a communication channel corresponding to a designated band (e.g., from about 6 GHz to about 60 GHz) among bands that are to be used for wireless communication with the second cellular network 294 or may support 5G communication via the established communication channel. The first communication processor 212 and/or the second communication processor 214 may communicate with the memory 130 and the processor 120 (e.g., an application processor (AP)).

According to an embodiment, the second cellular network 294 may be a 5G network or NR network defined by the 3rd generation partnership project (3GPP). According to an embodiment, according to an embodiment, the first communication processor 212 or the second communication processor 214 may establish a communication channel corresponding to another designated band (e.g., about 6 GHz or less) among the bands that are to be used for wireless communication with the second cellular network 294 or may support 5G communication via the established communication channel.

The first communication processor 212 may transmit/receive data and/or signals with the second communication processor 214. For example, data classified as transmitted via the second cellular network 294 may be changed to be transmitted via the first cellular network 292. In this case, the first communication processor 212 may receive transmission data from the second communication processor 214 and transmit the transmission data to the first cellular network 292. For example, the first communication processor 212 may transmit/receive data to/from the second communication processor 214 via an inter-processor interface 213. The inter-processor interface 213 may be implemented as, e.g., universal asynchronous receiver/transmitter (UART) (e.g., high speed-UART (HS-UART)) or peripheral component interconnect bus express (PCIe) interface, but is not limited to a specific kind. In an embodiment, the first communication processor 212 and the second communication processor 214 may exchange data and/or control signals using, e.g., shared memory. The first communication processor 212 may transmit/receive various types of information, such as sensing information, information about output strength, and resource block (RB) allocation information, to/from the second communication processor 214.

According to implementation, the first communication processor 212 may not be directly connected with the second communication processor 214. In this case, the first communication processor 212 may transmit/receive data to/from the second communication processor 214 via a processor 120. For example, the first communication processor 212 and the second communication processor 214 may transmit/receive data to/from the processor 120 (e.g., an application processor) via an HS-UART interface or PCIe interface, but the kind of the interface is not limited thereto. In an embodiment, the first communication processor 212 and the second communication processor 214 may exchange data and/or control signals using the processor 120 (e.g., an application processor) and shared memory (e.g., the memory 130).

According to an embodiment, the first CP 212 and the second CP 214 may be implemented in a single chip or a single package. According to an embodiment, the first communication processor 212 or the second communication processor 214, along with the processor 120, an assistance processor 123, or communication module 190, may be formed in a single chip or single package.

Referring to FIG. 2B, an integrated communication processor (e.g., including processing circuitry) 260 may be used instead of the first communication processor 212 and the second communication processor 214. The integrated communication processor 260 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions, and support both functions for communication with the first cellular network 292 and the second cellular network 294, is connected to the processor 120, and may be connected to at least one of the first transceiver 222, the second transceiver 224, or the fourth transceiver 228.

In an embodiment, when at least one of the processor 120, the first communication processor 212, the second communication processor 214, or the integrated communication processor 260 is implemented as a single chip or a single package, it may include memory (e.g., the memory 130) (or storage means) that stores instructions that cause the execution of at least some of the operations performed according to embodiments of the disclosure, and a processing circuit (or a computation circuit but it is not limited to a specific name) for executing the instructions.

Upon transmission, the first transceiver 222 may convert a baseband signal generated by the first communication processor 212 into a radio frequency (RF) signal with a designated frequency band (e.g., about 700 MHz to about 3 GHz) which is used by the first cellular network 292 (e.g., a legacy network). Upon reception, the RF signal may be received from the first cellular network 292 (e.g., a legacy network) through an antenna (e.g., the first antenna 242) and be pre-processed via an RFFE (e.g., the first RFFE 232). The first transceiver 222 may convert the pre-processed RF signal into a baseband signal that may be processed by the first communication processor 212.

Upon transmission, the second transceiver 224 may convert the baseband signal generated by the first communication processor 212 or the second communication processor 214 into an RF signal (hereinafter, Sub6G RF signal) with a designated frequency band (e.g., a Sub6G band below about 6 GHz) that is used by the second cellular network 294 (e.g., a 5G network). Upon reception, the Sub6G RF signal may be obtained from the second cellular network 294 (e.g., a 5G network) through an antenna (e.g., the second antenna 244) and be pre-processed via an RFFE (e.g., the second RFFE 234). The second transceiver 224 may convert the pre-processed 5G Sub6G RF signal into a baseband signal that may be processed by any one of the first communication processor 212 or the second communication processor 214.

The third transceiver 226 may convert the baseband signal generated by the second communication processor 214 into an RF signal (hereinafter, Above6G RF signal) with a designated frequency band (e.g., a 5G Above6G band from about 6 GHz to about that is to be used by the second cellular network 294 (e.g., a 5G network). Upon reception, the Above6G RF signal may be obtained from the second cellular network 294 (e.g., a 5G network) by an antenna (e.g., the antenna array 248) and be pre-processed via the third RFFE 236. The third transceiver 226 may convert the pre-processed 5G Above6G RF signal into a baseband signal that may be processed by the second communication processor 214. According to an embodiment, the third RFFE 236 may be formed separately from the third transceiver 226 or as part of the third RFIC 226.

The electronic device 101 may include the fourth transceiver 228 separately from or as part of the third transceiver 226. The fourth transceiver 228 may convert the baseband signal generated by the second communication processor 214 into a signal (hereinafter, an IF signal) with a designated intermediate frequency (IF) band (e.g., about 9 GHz to about 11 GHz) and transfer the IF signal to the third transceiver 226. The third transceiver 226 may convert the IF signal into a 5G Above6G RF signal. Upon reception, the 5G Above6G RF signal may be received from the second cellular network 294 (e.g., a 5G network) by an antenna (e.g., the antenna array 248) and be converted into an IF signal by the third transceiver 226. The fourth transceiver 228 may convert the IF signal into a baseband signal that may be processed by the second communication processor 214.

According to an embodiment, the first transceiver 222 and the second transceiver 224 may be implemented as at least part of a single chip or single package. According to an embodiment, when the first transceiver 222 and the second transceiver 224 in FIG. 2A or 2B are implemented as a single chip or a single package, they may be implemented as an integrated transceiver (not shown). The integrated transceiver is connected to the first RFFE 232 and the second RFFE 234 to convert a baseband signal into a signal of a frequency band supported by the first RFFE 232 and/or the second RFFE 234, and may transmit the converted signal to at least one of the first RFFE 232 and the second RFFE 234. According to an embodiment, the first RFFE 232 and the second RFFE 234 may be implemented as at least part of a single chip or single package. According to an embodiment, at least one of the first antenna 242 or the second antenna 244 may be omitted or be combined with another antenna module to process RF signals in a plurality of frequency bands.

According to an embodiment, the third transceiver 226 and the antenna array 248 may be disposed on the same substrate to form the Above6G module 246. For example, the wireless communication module 192 or the processor 120 may be disposed on a first substrate (e.g., a main painted circuit board (PCB)). In this case, the third transceiver 226 and the antenna array 248, respectively, may be disposed on a partial area (e.g., a lower surface) and another partial area (e.g., an upper surface) of a second substrate (e.g., a sub PCB) which is provided separately from the first substrate, forming the Above6G module 246. By placing the third transceiver 226 and the antenna array 248 on the same substrate (e.g., a sub PCB), it is possible to reduce the length of the transmission line between the third transceiver 226 and the antenna array 248. This may reduce a loss (e.g., attenuation) of high-frequency band (e.g., from about 6 GHz to about 60 GHz) signal used for 5G communication technology due to the transmission line. Thus, the electronic device 101 may enhance the communication quality with the second cellular network 294 (e.g., a 5G network).

According to an embodiment, the antenna array 248 may include a plurality of antenna elements available for beamforming. The Above6G module 246 may include a beamforming module (BF) 238 including a plurality of phase shifters (not shown) connected to the plurality of antenna elements, as part of the third RFFE 236. Upon transmission, each of the plurality of phase shifters may convert the phase of the 5G Above6G RF signal to be transmitted to an external device (e.g., a base station of the second cellular network 294) of the electronic device 101 through a corresponding antenna element. Upon reception, each of the plurality of phase shifters may convert the phase of the 5G Above6G RF signal to be transmitted to an external device (e.g., a base station of the second cellular network 294) of the electronic device 101 through a corresponding antenna element. The beamforming module 238 enables transmission or reception through beamforming between the electronic device 101 and the external device through the above-mentioned phase conversion.

The second cellular network 294 (e.g., a 5G network) may be operated independently (e.g., as standalone (SA)) from, or in connection (e.g., as non-standalone (NSA)) with the first cellular network 292 (e.g., a legacy network). For example, the 5G network may only include access networks (e.g., 5G radio access network (RAN) or next generation RAN (NG RAN)) and may not include core networks (e.g., next generation core (NGC)). After accessing the access network of the 5G network, the electronic device 101 may access the external network (e.g., the Internet) under the control of the core network (e.g., evolved packet core (EPC)) of the legacy network. Protocol information for communication with the legacy network (e.g., LTE protocol information) or protocol information for communication with the 5G network (e.g., NR protocol information) may be stored in the memory 130 and accessed by other components (e.g., the processor 120, the first communication processor 212, or the second communication processor 214).

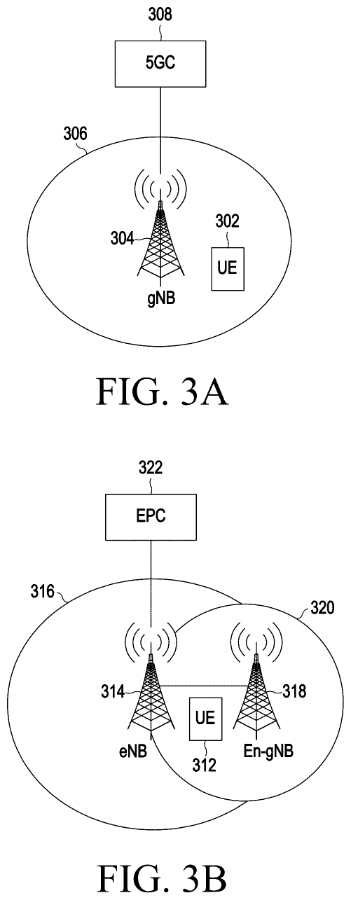

FIGS. 3A and 3B are diagrams illustrating example connection with a network according to various embodiments.

Referring to FIG. 3A, in a standalone (SA) structure, a user equipment (UE) 302 (e.g., the electronic device 101) may access a 5G network 308 (e.g., a 5G core network (5GC)) through a base station 304 (e.g., gNB (NG node B)) 304) using wireless communication technology (e.g., 5G communication technology). The gNB (NG node B) 304 may form the NG coverage 306 using 5G communication technology. The UE 302 may transmit and receive RF signals including data and/or control signals with the gNB 304.

Referring to FIG. 3B, in an EN-DC structure, a user equipment (UE) 312 (e.g., the electronic device 101) may access an LTE network (e.g., LTE core network (EPC)) 322 through an LTE base station (e.g., eNB (LTE node B)) 314 using a wireless communication technology (e.g., LTE communication technology) while simultaneously accessing the EPC 322 through a base station (e.g., EN-DC gNB (EN-gNB)) 318 using another wireless communication technology (e.g., 5G communication technology). The LTE coverage 316 formed by the eNB 314 may at least partially overlap the NG coverage 320 formed by the EN-gNB 318. The UE 312 located in the overlapping area may not only transmit and receive RF signals including data and/or control signals with the eNB 314, but also transmit and receive RF signals including data with the EN-gNB 318.

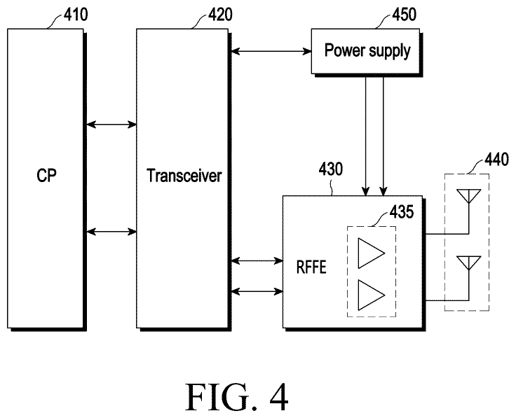

FIG. 4 is a block diagram illustrating an example configuration of a power supply for power amplification according to various embodiments.

Referring to FIG. 4, an electronic device 101 may include a communication processor (CP) (e.g., including processing circuitry) 410 (e.g., at least one of a processor 120, a first communication processor 212, a second communication processor 214, or an integrated communication processor 260), a transceiver 420 (e.g., at least one of a first transceiver 222, a second transceiver 224, a third transceiver 226, or a fourth transceiver 228), an RFFE 430 (e.g., at least one of a first RFFE 232, a second RFFE 234, or a third RFFE 236), an antenna 440, and/or a power supply 450.

The RFFE 430 may include one or more power amplifiers 435 for amplifying an RF signal in a designated frequency band. The power supply 450 may be electrically connected to the power amplifiers 435 in the RFFE 430, and may be configured to supply power (e.g., power supply voltage) to one or more power amplifiers 435. In an embodiment, the electronic device 101 such as the UE 302 or the UE 312 may support a plurality of RF bands. When the electronic device 101 is configured to support EN-DC, the power supply 450 may include one or more power supply circuits (e.g., envelope tracking (ET) modulators) for a plurality of power amplifiers 435 simultaneously operated for a plurality of RF signals in different RF bands (e.g., a 2G frequency band, a 3G frequency band, an LTE frequency band, and/or an NR frequency band).

The power supply 450 may include at least one ET modulator (e.g., the ET modulator 800) to increase the efficiency of the power amplifiers 435. The ET modulator may be configured to provide the power amplifiers 435 with a power supply voltage of a corresponding magnitude for the transmission power required at each transmission moment. In an embodiment, the ET modulator (e.g., the ET modulator 800) may operate in ET mode or average power tracking (APT) mode, and variably adjust the amplitude of the power supply voltage applied to the power amplifiers 435 according to transmission signal information input to the power amplifiers 435 from the transceiver 420 (e.g., transmission envelope waveform in the case of the ET mode or the average power in the case of the APT mode), allowing the power amplifiers 435 to operate at the maximum efficiency.

In an embodiment, the power output from the ET modulator in the ET mode may be referred to as an ET power supply voltage or ET power, and the power output from the ET modulator in the APT mode may be referred to as an APT power supply voltage or APT power. The ET power may have a magnitude that varies according to the transmission envelope waveform of the RF signal to be transmitted via the RFFE 430. The APT power may have a magnitude that varies according to the average power of the RF signal to be transmitted via the RFFE 430.

In an embodiment, the magnitude of the voltage provided by the power supply 450 may be adjusted according to the RF signal to be transmitted in a frequency band (e.g., an RF band) corresponding to the communication technology used in the electronic device 101. In an embodiment, the power supply 450 may be electrically connected to the battery (e.g., the battery 189) of the electronic device 101, and may perform a step-up or step-down operation on the output voltage V_{batt} of the battery 189. The power supply 450 may provide power generated based on the step-up operation or the step-down operation to the power amplifiers 435. Each ET modulator in the power supply 450 may be connected to one or more PAs in the RFFE 430.

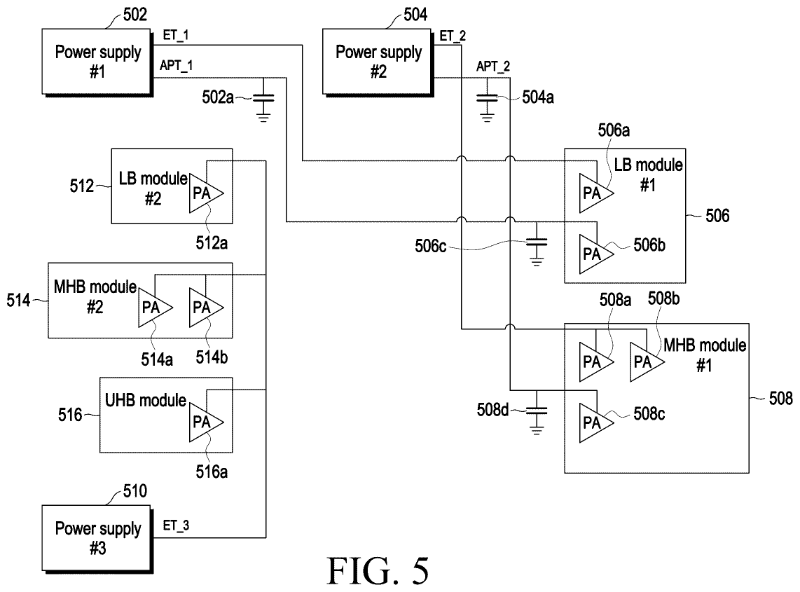

FIG. 5 is a diagram illustrating an example power supply structure including three power supplies according to various embodiments.

Referring to FIG. 5, first power supply #1 502, power supply #2 504, and power supply #3 510 may correspond to the power supply 450 of FIG. 4. The RFFE 430 may include one or more PA modules (e.g., at least one of low band (LB) module #1 506, middle and high band (MHB) module #1 508, LB module #2 512, MHB module #2 514, or at least one ultra-high band (UHB) module 516).

In an embodiment, LB module #1 506 and/or LB module #2 512 may be configured to amplify RF signals of a designated LB (e.g., less than about 1 GHz) among RF bands of a first radio access technology (RAT) and RF bands of a second RAT. In an embodiment, the first RAT may include at least one of a first wireless communication scheme (e.g., 2G communication technology) or a satellite communication scheme. In an embodiment, the second RAT may include at least one of a second wireless communication scheme (e.g., 4G/LTE communication technology) or a third wireless communication scheme (e.g., 5G/NR communication technology).

In an embodiment, MHB module #1 508 and/or MHB module #2 514 may be configured to amplify RF signals of a designated middle band (MB) (e.g., about 1 GHz to 2.3 GHz) and a designated high band (HB) (e.g., about 2.3 GHz to 2.7 GHz) among the RF bands of the first RAT and/or the RF bands of the second RAT.

In an embodiment, at least one of LB module #1 506 and MHB module #1 508 includes a low noise amplifier (LNA) power amplifier module with integrated duplexer (L-PAMiD), and may be responsible for the main path of 2G, 3G, LTE, NR SA (standalone), and NR DC (dual connectivity). In an embodiment, at least one of LB module #2 512 and MHB module #2 514 includes a PA module and may be responsible for a secondary path of LTE or NR DC (dual connectivity).

In an embodiment, at least one UHB module 516 may include at least one PA (e.g., the UHB PA 516a) configured to amplify RF signals of a designated UHB (e.g., an n77 band of about 3.3 GHz to 4.2 GHz and/or an n78 band of about 3.3 GHz to 3.8 GHz) among the RF bands of 5G communication technology.

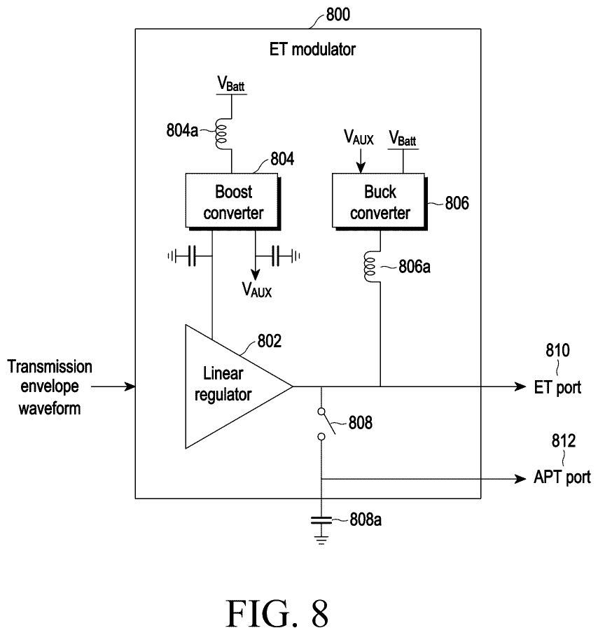

In an embodiment, each of power supply #1 502, power supply #2 504, and/or power supply #3 510 may include the ET modulator 800 of FIG. 8. For example, power supply #1 502 may be configured to output either the first ET power ET_1 or the first APT power APT_1 through the ET port, or the first APT power APT_1 through the APT port. For example, power supply #2 504 may be configured to output either the second ET power ET_2 or the second APT power APT_1 through the ET port, or the second APT power APT_2 through the APT port. For example, power supply #3 510 may be configured to output the third ET power ET_3 through the ET port.

In an embodiment, LB module #1 506 may include a first LB PA 506a (e.g., PA for LTE/NR LB) configured to amplify RF signals corresponding to the LB of the second RAT (e.g., LTE and NR communication technology), and a second LB PA 506b (e.g., PA for 2G LB) configured to amplify RF signals corresponding to the LB of the first RAT (e.g., 2G communication technology). The first LB PA 506a may operate based on ET_1 from power supply #1 502. The second LB PA 506b may operate based on APT_1 from power supply #1 502. A decoupling capacitor (decap) 502a (e.g., a capacitor of about 4.7 μF) for removing noise may be connected to the output port of power supply #1 502 supplying APT_1, and a decoupling capacitor 506c (e.g., a capacitor of about 1 μF) for removing noise may be connected to the input port of LB module #1 506 receiving APT_1.

In an embodiment, MHB module #1 508 may include a first MB PA 508a (e.g., PA for LTE/NR MB) configured to amplify RF signals corresponding to the MB of the second RAT (e.g., LTE and NR communication technology), a first HB PA 508b (e.g., PA for LTE/NR HB) configured to amplify RF signals corresponding to the HB of the second RAT, or a second MB PA 508c configured to amplify RF signals corresponding to the MB of the first RAT (e.g., 2G communication technology). The first MB PA 508a and the first HB PA 508b may operate based on ET_2 from power supply #2 504. The second MB PA 508c may operate based on APT_2 from power supply #2 502. A decoupling capacitor (decap) 504a (e.g., a capacitor of about 4.7 μF) for removing noise may be connected to the output port of power supply #2 504 supplying APT_2, and a decoupling capacitor 508d (e.g., a capacitor of about 1 μF) for removing noise may be connected to the input port of MHB module #1 508 receiving APT_2.

In an embodiment, LB module #2 512 may include a third LB PA 512a (e.g., PA for LTE/NR LB) configured to amplify RF signals corresponding to the LB of the second RAT (e.g., LTE and NR communication technology). The third LB PA 512a may operate based on ET_3 from power supply #3 510. In an embodiment, MHB module #2 514 may include a third MB PA 514a (e.g., PA for LTE/NR MB) configured to amplify RF signals corresponding to MB of the second RAT (e.g., LTE and NR communication technology), and/or a second HB PA 514b (e.g., PA for LTE/NR HB) configured to amplify RF signals corresponding to HB of the second RAT. The third MB PA 514a and the second HB PA 514b may operate based on ET_3 from power supply #3 510.

In an embodiment, at least one UHB module 516 may include a UHB PA 516a configured to amplify RF signals of a designated UHB (e.g., n77 band and/or n78 band) among the RF bands of 5G communication technology. The UHB PA 516a may operate based on ET_3 from power supply #3 510.

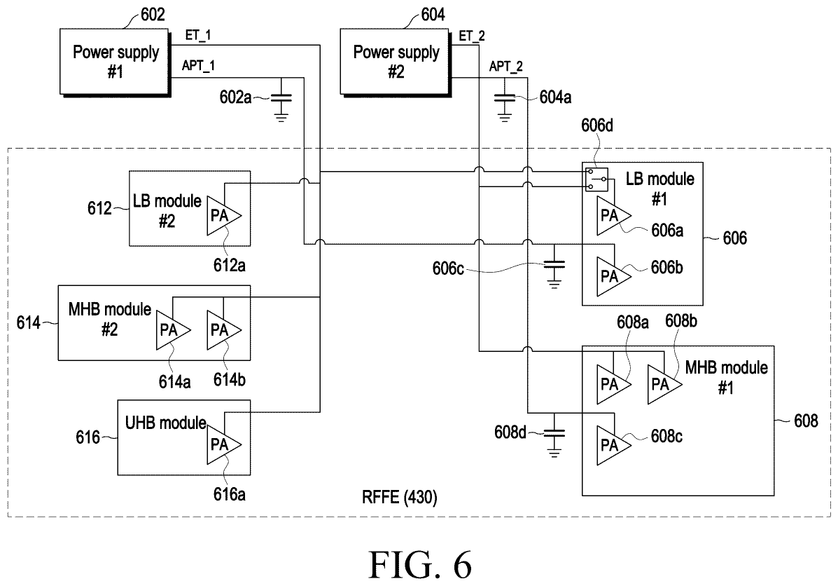

FIG. 6 is a diagram illustrating an example power supply structure including two power supplies according to various embodiments.

Referring to FIG. 6, power supply #1 602 and power supply #2 604 may correspond to the power supply 450 of FIG. 4. The RFFE 430 may include one or more PA modules (e.g., at least one of LB module #1 606, MHB module #1 608, LB module #2 612, MHB module #2 614, or at least one UHB module 616).

In an embodiment, LB module #1 606 and/or LB module #2 612 may be configured to amplify RF signals of a designated LB (e.g., less than about 1 GHz) among RF bands of a first RAT (e.g., 2G communication technology) and/or RF bands of a second RAT (e.g., 4G/LTE communication technology and/or 5G/NR communication technology). In an embodiment, MHB module #1 608 and/or MHB module #2 614 may be configured to amplify RF signals of a designated MB (e.g., about 1.4 GHz to 2.3 GHz) and a designated HB (e.g., about 2.3 GHz to 2.7 GHz) among the RF bands of the first RAT and/or the RF bands of the second RAT. In an embodiment, at least one of LB module #1 606 and MHB module #1 608 includes an L-PAMiD, and may be responsible for the main path of 2G, 3G, LTE, NR SA, and NR DC.

In an embodiment, at least one UHB module 616 may include at least one UHB PA (e.g., the UHB PA 616a) configured to amplify RF signals of a designated UHB (e.g., n77 band and/or n78 band) among the RF bands of 5G communication technology.

In an embodiment, each of power supply #1 602 and power supply #2 604 may include the ET modulator 800 of FIG. 8. Power supply #1 602 may be configured to output either the first ET power ET_1 or the first APT power APT_1 through the ET port, or the first APT power APT_1 through the APT port. Power supply #2 604 may be configured to output either the second ET power ET_2 or the second APT power APT_1 through the ET port, or the second APT power APT_2 through the APT port.

In an embodiment, LB module #1 606 may include a first LB PA 606a (e.g., PA for LTE/NR LB) configured to amplify RF signals corresponding to the LB of the second RAT, a second LB PA 606b (e.g., PA for 2G LB) configured to amplify RF signals corresponding to the LB of the first RAT, and a switch 606d (e.g., a power supply switch) for selecting power provided to the first LB PA 606a. The switch 606d may select any one of ET_1 from power supply #1 602 and ET_2 from power supply #2 604 under the control of the processor (e.g., the CP 410 or the processor 120) and provide it to the first LB PA 606a. The first LB PA 606a may operate based on power (e.g., ET_1 or ET_2) provided through the switch 606d. The second LB PA 606b may operate based on APT_1 from power supply #1 602. A decoupling capacitor (decap) 602a (e.g., a capacitor of about 4.7 μF) for removing noise may be connected to the output port of power supply #1 602 supplying APT_1, and a decoupling capacitor 606c (e.g., a capacitor of about 1 μF) for removing noise may be connected to the input port of LB module #1 606 receiving APT_1.

In an embodiment, MHB module #1 608 may include a first MB PA 608a (e.g., PA for LTE/NR MB) configured to amplify RF signals corresponding to the MB of the second RAT (e.g., LTE and NR communication technology), a first HB PA 608b (e.g., PA for LTE/NR HB) configured to amplify RF signals corresponding to the HB of the second RAT, or a second MB PA 608c configured to amplify RF signals corresponding to the MB of the first RAT (e.g., 2G communication technology). The first MB PA 608a and the first HB PA 608b may operate based on ET_2 from power supply #2 604. The second MB PA 608c may operate based on APT_2 from power supply #2 602. A decoupling capacitor (decap) 604a (e.g., a capacitor of about 4.7 μF) for removing noise may be connected to the output port of power supply #2 604 supplying APT_2, and a decoupling capacitor 608d (e.g., a capacitor of about 1 μF) may be connected to the input port of MHB module #1 608 receiving APT_2.

In an embodiment, LB module #2 612 may include a third LB PA 612a (e.g., PA for LTE/NR LB) configured to amplify RF signals corresponding to the LB of the second RAT (e.g., LTE and NR communication technology). The first LB PA 612a may operate based on ET_1 from power supply #3 602. In an embodiment, MHB module #2 614 may include a third MB PA 614a (e.g., PA for LTE/NR MB) configured to amplify RF signals corresponding to MB of the second RAT (e.g., LTE and NR communication technology), and a second HB PA 614b (e.g., PA for LTE/NR HB) configured to amplify RF signals corresponding to HB of the second RAT. The third MB PA 614a and the second HB PA 614b may operate based on ET_1 from power supply #1 602.

In an embodiment, at least one UHB module 616 may include a UHB PA 616a configured to amplify RF signals of a designated UHB (e.g., n77 band and/or n78 band) among the RF bands of 5G communication technology. The UHB PA 616a may operate based on ET_1 from power supply #1 602.

As compared with the power supply structure of FIG. 5, the power supply structure of FIG. 6 may downsize the RF circuit structure and reduce the mounting area by deleting power supply #3 510 and using the switch 606d for power supply.

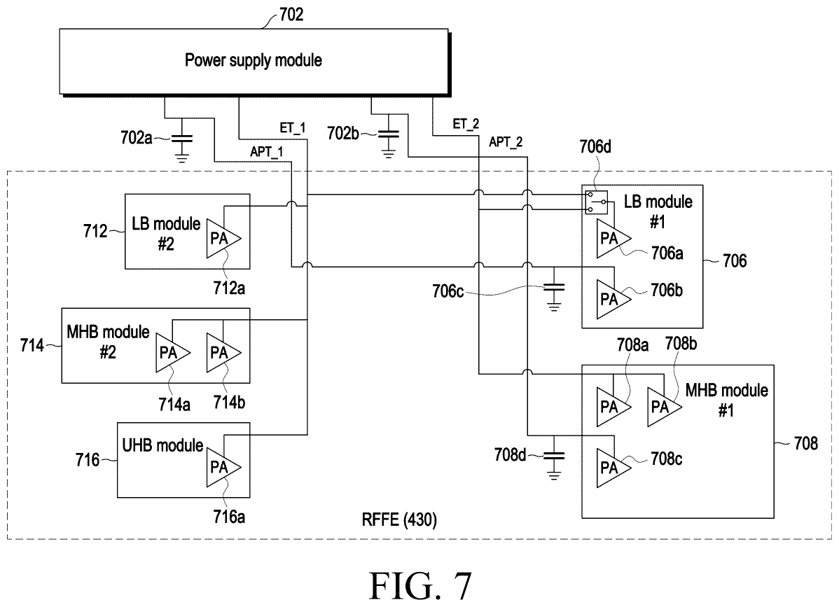

FIG. 7 is a diagram illustrating an example power supply structure including one power supply module according to various embodiments.

Referring to FIG. 7, a power supply module 702 may correspond to the power supply 450 of FIG. 4. In an embodiment, the power supply module 702 may include two ET modulators (e.g., the ET modulator 800 of FIG. 8). The RFFE 430 may include one or more PA modules (e.g., at least one of LB module #1 706, MHB module #1 708, LB module #2 712, MHB module #2 714, or at least one UHB module 716).

In an embodiment, the power supply module 702 may include two ET modulators (e.g., the ET modulator 800 of FIG. 8). The power supply module 702 may be configured to output any one of the first ET power ET_1 and the first APT power APT_1, or to output any one of the second ET power ET_2 and the second APT power A PT_1.

In an embodiment, LB module #1 706 may include a first LB PA 706a configured to amplify RF signals corresponding to the LB of the second RAT, a second LB PA 706b configured to amplify RF signals corresponding to the LB of the first RAT, and a switch 706d for selecting power provided to the first LB PA 706a. The switch 706d may select any one of ET_1 and ET_2 from the power supply module 702 under the control of the processor (e.g., the CP 410 or the processor 120) and provide it to the first LB PA 706a. The second LB PA 706b may operate based on APT_1 from the power supply module 702. A decoupling capacitor (decap) 702a (e.g., a capacitor of about 4.7 μF) for removing noise may be connected to the output port of the power supply module 702 supplying APT_1, and a decoupling capacitor 706c (e.g., a capacitor of about 1 μF) for removing noise may be connected to the input port of LB module #1 706 receiving APT_1.

In an embodiment, MHB module #1 708 may include a first MB PA 708a configured to amplify RF signals corresponding to the MB of the second RAT, a first HB PA 708b configured to amplify RF signals corresponding to the HB of the second RAT, and a second MB PA 708c configured to amplify RF signals corresponding to the MB of the first RAT. The first MB PA 708a and the first HB PA 708b may operate based on ET_2 from the power supply module 702. The second MB PA 708c may operate based on APT_2 from the power supply module 702. A decoupling capacitor (decap) 702b (e.g., a capacitor of about 4.7 μF) for removing noise may be connected to the output port of the power supply module 704 supplying APT_2, and a decoupling capacitor 708d (e.g., a capacitor of about 1 μF) may be connected to the input port of MHB module #1 708 receiving APT_2.

In an embodiment, LB module #2 712 may include a third LB PA 712a configured to amplify RF signals corresponding to the LB of the second RAT. The third LB PA 712a may operate based on ET_1 from the power supply module 702. In an embodiment, MHB module #2 714 may include a third MB PA 714a configured to amplify RF signals corresponding to the MB of the second RAT and a second HB PA 714b configured to amplify RF signals corresponding to the HB of the second RAT. The third MB PA 714a and the second HB PA 714b may operate based on ET_1 from the power supply module 702.

In an embodiment, at least one UHB module 716 may include a PA (e.g., the UHB PA 716a) configured to amplify RF signals of a designated UHB (e.g., n77 band and/or n78 band) among the RF bands of 5G communication technology. The UHB PA 716a may operate based on ET_1 from the power supply module 702.

The power supply structure of FIG. 7 may be further downsized using one power supply module 702, as compared with the power supply structure of FIG. 6, which uses two power supplies 602 and 604.

FIG. 8 is a diagram illustrating an example structure of an ET modulator according to various embodiments.

Referring to FIG. 8, an ET modulator 800 (e.g., power supply #1 502, power supply #2 504, power supply #1 602, power supply #2 604, and/or the power supply module 702) may include a linear regulator 802, a boost converter 804, a buck converter 806, an ET port 810, and/or an APT port 812. In an embodiment, the ET modulator 800 may include a switching converter and/or a switching regulator instead of or in addition to the linear regulator 802. The ET port 810 is directly connected to the output of the linear regulator 802, and the APT port 812 may be connected to the output of the linear regulator 802 through the APT switch 808. The ET modulator 800 may output power (e.g., APT_1 and/or APT_2) through the APT port 812, or output power (e.g., APT_1 and/or APT_2) or modulated power (e.g., ET_1 and/or ET_2) through the ET port 810.

In an embodiment, the boost converter 804 (e.g., a step-up converter) is a direct current to direct current (DC-DC) converter that increases the output voltage with respect to the input voltage (e.g., the voltage V_{batt} of the battery (e.g., the battery 189)). The boost converter 804 may perform a boosting operation based on the voltage V_{batt} of the battery (e.g., the battery 189) charged to the inductor 804a. The output voltage increased by the boost converter 804 may be provided as a power supply voltage of the linear regulator 802. The boost converter 804 may also generate an auxiliary voltage V_{AUX} for the buck converter 806.

In an embodiment, the buck converter 806 (e.g., a step-down converter) is a DC-DC converter that reduces the output voltage with respect to the input voltage (e.g., the voltage V_{batt} of the battery (e.g., the battery 189)) based on the auxiliary voltage V_{Aux}. The buck converter 806 may perform a step-down operation based on the voltage V_{batt} of the battery (e.g., the battery 189). An inductor 806a may be connected between the output of the buck converter 806 and the output of the linear regulator 802, and the output voltage of the buck converter 806 may be charged to the inductor 806a.

In an embodiment, in the ET mode, the APT switch 808 connected between the output of the linear regulator 802 and the APT port 812 may be turned off. The linear regulator 802 may receive the envelope waveform of the transmission signal as an input and amplify the envelope waveform of the transmission signal based on the power supply voltage provided from the boost converter 804. The output voltage of the linear regulator 802 may be output to the ET port 810 and become an ET power (e.g., ET_1 or ET_2) having a magnitude varying according to the envelope waveform of the transmission signal.

In an embodiment, in the APT mode, the APT switch 808 may be turned on to connect the output of the inductor 806a to the APT port 812, and the voltage charged to the inductor 806a may be output as an APT power (e.g., APT_1 or APT_2) through the APT port 812. A decoupling capacitor 808a (e.g., a capacitor of about 4.7 μF) for removing noise may be connected to the APT port 812.

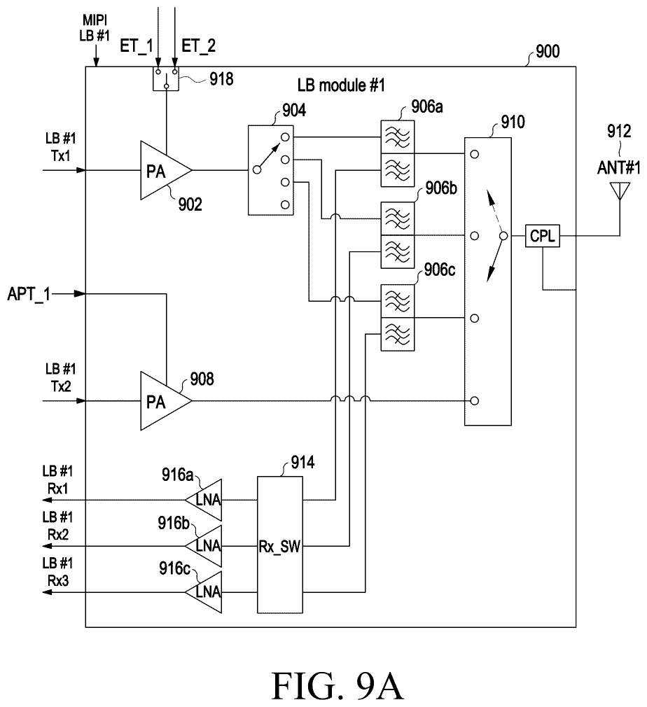

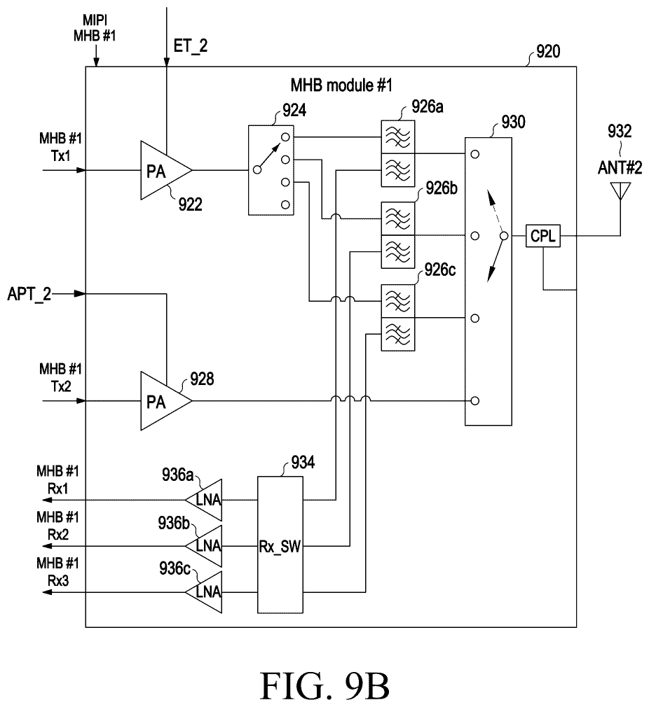

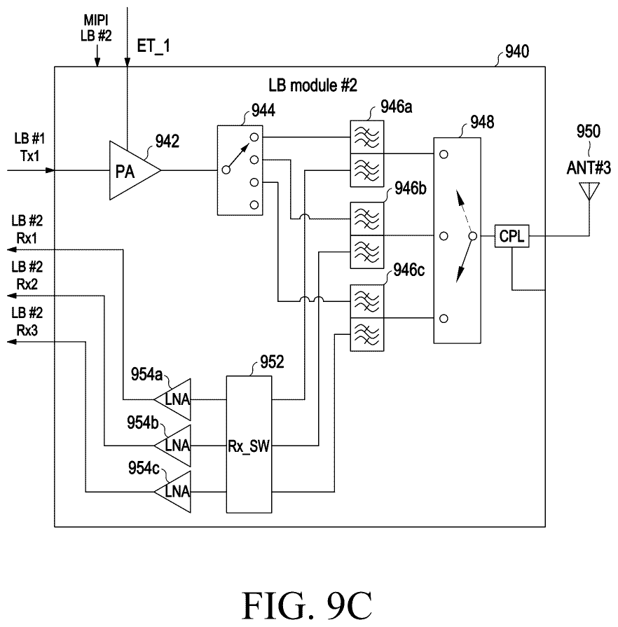

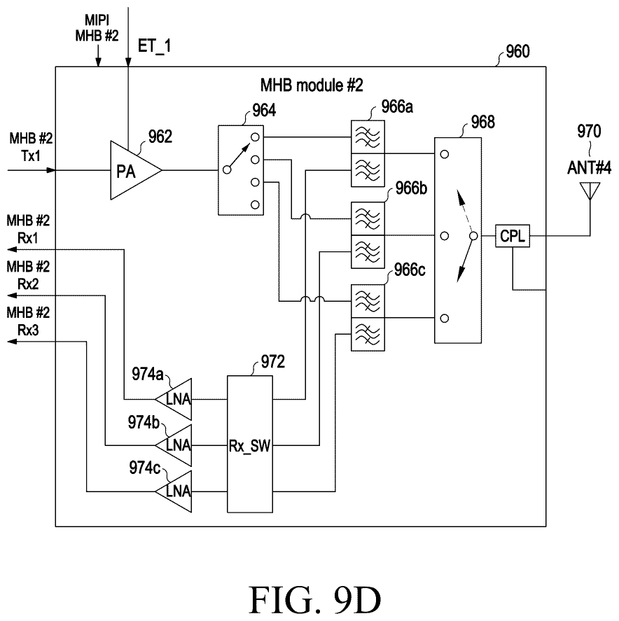

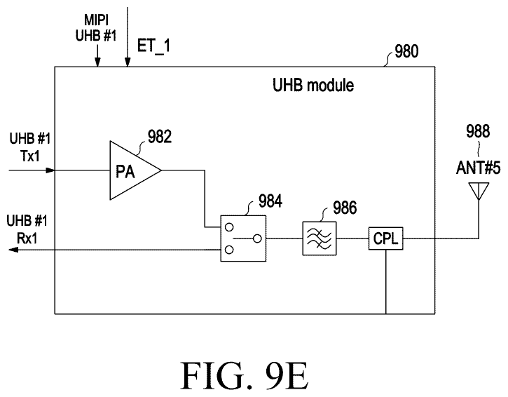

FIGS. 9A, 9B, 9C, 9D, and 9E are diagrams illustrating example structures of PA modules according to various embodiments.

Referring to FIG. 9A, LB module #1 900 (e.g., LB module #1 606, or LB module #1 706) may include a first PA 902 (e.g., the first LB PA 606a or the first LB PA 706a), a transmit switch (Tx_SW) 904, a first duplexer 906a, a second duplexer 906b, a third duplexer 906c, a second PA 908 (e.g., the second LB PA 606b or the second LB PA 706b), an antenna switch (Ant_SW) 910, a receive switch (Rx_SW) 914, a first LNA 916a, a second LNA 916b, a third LNA 916c, and/or a switch 918 (e.g., the switch 606d or the switch 706d).

In an embodiment, in the transmission mode of the second RAT (e.g., LTE and/or NR communication technology), LB module #1 900 may receive an RF signal (e.g., a transmission signal) in a designated frequency band (e.g., LB) generated using the second RAT from the transceiver (e.g., the transceiver 420). The transmission signal may be input to the first PA 902 through a designated transmission fin (e.g., LB #1 Tx1). The switch 918 may select any one of two powers (e.g., ET_1 and ET_2) provided from the power supply 450 (e.g., power supply #1 602, power supply #2 604, or the power supply module 702) and supply the selected power to the first PA 902. The first PA 902 may amplify the transmission signal based on a designated amplification gain based on the power (e.g., ET_1 or ET_2) provided through the switch 918, and then transfer the amplified signal to the transmit switch 904.

The transmit switch 904 may perform a switching operation so that a signal transferred from the first PA 902 is input to a corresponding duplexer (e.g., any one of the duplexers 906a, 906b, and 906c). In an embodiment, when LB module #1 900 may support a total of three bands of a first band, a second band, and a third band, the transmit switch 904 may transfer a signal corresponding to the first band to the first duplexer 906a, transfer a signal corresponding to the second band to the second duplexer 906b, and transfer a signal corresponding to the third band to the third duplexer 906c. The first duplexer 906a, the second duplexer 906b, and the third duplexer 906c may be configured to perform band pass filtering (BPF) on the received signals based on corresponding bands (e.g., the first band, the second band, and the third band).

For example, the signal transferred from the transmit switch 904 may be input to the first duplexer 906a, and in the transmission mode, the first duplexer 906a may filter the signal input from the transmit switch 904 and then transfer it to the antenna switch 910. For example, the signal transferred from the transmit switch 904 may be input to the second duplexer 906b, and in the transmission mode, the second duplexer 906b may filter the signal input from the transmit switch 904 and then transfer it to the antenna switch 910. For example, the signal transferred from the transmit switch 904 may be input to the third duplexer 906c, and in the transmission mode, the third duplexer 906c may filter the signal input from the transmit switch 904 and then transfer it to the antenna switch 910.

In an embodiment, in the transmission mode of the first RAT (e.g., 2G communication technology), LB module #1 900 may receive an RF signal (e.g., a transmission signal) in a designated frequency band (e.g., LB) generated using the first RAT from the transceiver (e.g., the transceiver 420). The transmission signal may be input to the second PA 908 through a designated transmission fin (e.g., LB #1 Tx2). The second PA 908 may amplify the transmission signal based on a designated amplification gain based on a power (e.g., APT_1) provided from the power supply 450 (e.g., power supply #1 602 or the power supply module 702), and then transfer the amplified signal to the antenna switch 910.

In an embodiment, the antenna switch 910 may transfer any one of a signal input from the first duplexer 906a,a signal input from the second duplexer 906b, a signal input from the third duplexer 906c, or a signal input from the second PA 908 to the first antenna (ANT #1) 912 to be wirelessly transmitted by the first antenna (ANT #1) 912. In an embodiment, a coupler CPL may be connected to a front end of the first antenna (ANT #1) 912.

In an embodiment, a signal (e.g., a reception signal) in a designated frequency band (e.g., LB) received through the first antenna 912 may be input to the antenna switch 910, and the antenna switch 910 may perform a switching operation so that the reception signal received through the first antenna 912 is transferred to any one of the first duplexer 906a, the second duplexer 906b, or the third duplexer 906c.

For example, the reception signal transferred from the antenna switch 910 may be input to the first duplexer 906a, and in the reception mode, the first duplexer 906a may transfer the reception signal transferred from the antenna switch 910 to the receive switch 914. For example, the reception signal transferred from the antenna switch 910 may be input to the second duplexer 906b, and in the reception mode, the second duplexer 906b may transfer the signal input from the antenna switch 910 to the receive switch 914. For example, the reception signal transferred from the antenna switch 910 may be input to the third duplexer 906c, and in the reception mode, the third duplexer 906c may transfer the signal input from the antenna switch 910 to the receive switch 914.

In an embodiment, the receive switch 914 may transfer a signal input from the first duplexer 906a to the first LNA 916a. The first LNA 916a may perform a low noise amplification operation based on a designated amplification gain on the signal input from the receive switch 914, and then transfer the amplified signal to the transceiver (e.g., the transceiver 420) through a designated reception fin (e.g., LB #1 Rx1). In an embodiment, the receive switch 914 may transfer a signal input from the second duplexer 906b to the second LNA 916b. The second LNA 916b may perform a low noise amplification operation based on a designated amplification gain on the signal input from the receive switch 914, and then transfer the amplified signal to the transceiver through a designated reception fin (e.g., LB #1 Rx2). In an embodiment, the receive switch 914 may transfer a signal input from the third duplexer 906c to the third LNA 916c. The third LNA 916c may perform a low noise amplification operation based on a designated amplification gain on the signal input from the receive switch 914 and then transfer the amplified signal to the transceiver through a designated reception fin (e.g., LB #1 Rx3).

Referring to FIG. 9B, MHB module #1 920 (e.g., MHB module #1 608 or MHB module #1 708) may include at least one first PA 922 (e.g., the first MB PA 608a, the first HB PA 608b, the first MB PA 708a, or the first HB PA 708b), a transmit switch (Tx_SW) 924, a first duplexer 926a, a second duplexer 926b, a third duplexer 926c, a second PA 928 (e.g., the second MB PA 608c or the second MB PA 708c), an antenna switch (Ant_SW) 930, a receive switch (Rx_SW) 934, a first LNA 936a, a second LNA 936b, and/or a third LNA 936c.

In an embodiment, in the transmission mode of the second RAT (e.g., LTE and/or NR communication technology), MHB module #1 920 may receive an RF signal (e.g., a transmission signal) in a designated frequency band (e.g., MB or HB) generated using the second RAT from the transceiver (e.g., the transceiver 420). The transmission signal may be input to the first PA 922 through a designated transmission fin (e.g., MHB #1 Tx1). The first PA 922 may amplify the transmission signal based on a designated amplification gain based on a power (e.g., ET_2) provided from the power supply 450 (e.g., power supply #2 604 or the power supply module 702), and then transfer the amplified signal to the transmit switch 924.

The transmit switch 924 may perform a switching operation so that a signal transferred from the first PA 922 is input to a corresponding duplexer (e.g., any one of the duplexers 926a, 926b, and 926c). In an embodiment, when MHB module #1 920 may support a total of three bands of a first band, a second band, and a third band, the transmit switch 924 may transfer a signal corresponding to the first band to the first duplexer 926a, transfer a signal corresponding to the second band to the second duplexer 926b, and transfer a signal corresponding to the third band to the third duplexer 926c. In the transmission mode, any one of the first duplexer 926a, the second duplexer 926b, or the third duplexer 926c may transfer a signal input from the transmit switch 924 to the antenna switch 930. For example, the first duplexer 926a, the second duplexer 926b, and the third duplexer 926c may be configured to perform band pass filtering (BPF) on the received signals based on corresponding bands (e.g., the first band, the second band, and the third band).

In an embodiment, in the transmission mode of the first RAT (e.g., 2G communication technology), MHB module #1 920 may receive an RF signal (e.g., a transmission signal) in a designated frequency band (e.g., MB) generated using the first RAT from the transceiver (e.g., the transceiver 420). The transmission signal may be input to the second PA 928 through a designated transmission fin (e.g., MHB #1 Tx2). The second PA 928 may amplify the transmission signal based on a designated amplification gain based on a power (e.g., APT_2) provided from the power supply 450 (e.g., power supply #2 604 or the power supply module 702), and then transfer the amplified signal to the antenna switch 930.

In an embodiment, the antenna switch 930 may transfer any one of a signal input from the first duplexer 926a, a signal input from the second duplexer 926b, a signal input from the third duplexer 926c, or a signal input from the second PA 928 to the second antenna (ANT #2) 932 to be wirelessly transmitted by the second antenna (ANT #2) 932. In an embodiment, a coupler CPL may be connected to a front end of the second antenna (ANT #2) 932 as necessary.

In an embodiment, a signal (e.g., a reception signal) in a designated frequency band (e.g., MB or HB) received through the second antenna 932 may be input to the antenna switch 930, and the antenna switch 930 may perform a switching operation so that the reception signal received through the second antenna 932 is transferred to any one of the first duplexer 926a, the second duplexer 926b, or the third duplexer 926c. For example, in the reception mode, any one of the first duplexer 926a, the second duplexer 926b, or the third duplexer 926c may transfer a signal transferred from the antenna switch 930 to the receive switch 934.

In an embodiment, the receive switch 934 may transfer a signal input from the first duplexer 926a to the first LNA 936a. The first LNA 926a may perform a low noise amplification operation based on a designated amplification gain on the signal input from the receive switch 934 and then transfer the amplified signal to the transceiver through a designated reception fin (e.g., MHB #1 Rx1). In an embodiment, the receive switch 934 may transfer a signal input from the second duplexer 926b to the second LNA 936b. The second LNA 936b may perform a low noise amplification operation based on a designated amplification gain on the signal input from the receive switch 934, and then transfer the amplified signal to the transceiver through a designated reception fin (e.g., MHB #1 Rx2). In an embodiment, the receive switch 934 may transfer a signal input from the third duplexer 926c to the third LNA 936c. The third LNA 936c may perform a low noise amplification operation based on a designated amplification gain on the signal input from the receive switch 934 and then transfer the amplified signal to the transceiver through a designated reception fin (e.g., MHB #1 Rx3).

Referring to FIG. 9C, LB module #2 940 (e.g., LB module #2 612 or LB module #1 712) may include at least one first PA 942 (e.g., the third LB PA 612a or the third LB PA 712a), a transmit switch (Tx_SW) 944, a first duplexer 946a, a second duplexer 946b, a third duplexer 946c, an antenna switch (Ant_SW) 948, a receive switch (Rx_SW) 952, a first LNA 954a, a second LNA 954b, and/or a third LNA 954c.

In an embodiment, in the transmission mode of the second RAT (e.g., LTE and/or NR communication technology), LB module #2 940 may receive an RF signal (e.g., a transmission signal) in a designated frequency band (e.g., LB) generated using the second RAT from the transceiver (e.g., the transceiver 420). The transmission signal may be input to the first PA 942 through a designated transmission fin (e.g., LB #2 Tx1). The first PA 942 may amplify the transmission signal based on a designated amplification gain based on a power (e.g., ET_1) provided from the power supply 450 (e.g., power supply #1 602 or the power supply module 702), and then transfer the amplified signal to the transmit switch 944.

The transmit switch 944 may perform a switching operation so that a signal transferred from the first PA 942 is input to a corresponding duplexer (e.g., any one of the duplexers 946a, 946b, and 946c). In an embodiment, when LB module #1 940 may support a total of three bands of a first band, a second band, and a third band, the transmit switch 944 may transfer a signal corresponding to the first band to the first duplexer 946a, transfer a signal corresponding to the second band to the second duplexer 946b, and transfer a signal corresponding to the third band to the third duplexer 946c. In the transmission mode, any one of the first duplexer 946a, the second duplexer 946b, or the third duplexer 946c may transfer a signal input from the transmit switch 944 to the antenna switch 948. The first duplexer 946a, the second duplexer 946b, and the third duplexer 946c may be configured to perform band pass filtering (BPF) on the received signals based on corresponding bands (e.g., the first band, the second band, and the third band).

In an embodiment, the antenna switch 948 may transfer any one of a signal input from the first duplexer 946a, a signal input from the second duplexer 946b, or a signal input from the third duplexer 946c to the third antenna (ANT #3) 950 to be wirelessly transmitted by the third antenna (ANT #3) 950. In an embodiment, a coupler CPL may be connected to a front end of the third antenna (ANT #3) 950 as necessary.

In an embodiment, a signal (e.g., a reception signal) in a designated frequency band (e.g., LB) received through the third antenna 950 may be input to the antenna switch 948, and the antenna switch 948 may perform a switching operation so that the reception signal received through the third antenna 948 is transferred to any one of the first duplexer 946a, the second duplexer 946b, or the third duplexer 946c. For example, in the reception mode, any one of the first duplexer 946a, the second duplexer 946b, or the third duplexer 946c may transfer a signal transferred from the antenna switch 948 to the receive switch 952.

In an embodiment, the receive switch 952 may transfer a signal input from the first duplexer 946a to the first LNA 954a. The first LNA 954a may perform a low noise amplification operation based on a designated amplification gain on the signal input from the receive switch 952 and then transfer the amplified signal to the transceiver through a designated reception fin (e.g., LB #2 Rx1). In an embodiment, the receive switch 952 may transfer a signal input from the second duplexer 946b to the second LNA 954b. The second LNA 954b may perform a low noise amplification operation based on a designated amplification gain on the signal input from the receive switch 952, and then transfer the amplified signal to the transceiver through a designated reception fin (e.g., LB #2 Rx2). In an embodiment, the receive switch 952 may transfer a signal input from the third duplexer 946c to the third LNA 954c. The third LNA 954c may perform a low noise amplification operation based on a designated amplification gain on the signal input from the receive switch 952 and then transfer the amplified signal to the transceiver through a designated reception fin (e.g., LB #2 Rx3).

Referring to FIG. 9D, MHB module #2 960 (e.g., MHB module #2 614 or MHB module #2 714) may include at least one first PA 962 (e.g., the third MB PA 614a, the second HB PA 614b, the third MB PA 714a, or the second HB PA 714b), a transmit switch (Tx_SW) 964, a first duplexer 966a, a second duplexer 966b, a third duplexer 966c, an antenna switch (Ant_SW) 968, a receive switch (Rx_SW) 972, a first LNA 974a, a second LNA 974b, and/or a third LNA 974c.

In an embodiment, in the transmission mode of the second RAT (e.g., LTE and/or NR communication technology), MHB module #2 960 may receive an RF signal (e.g., a transmission signal) in a designated frequency band (e.g., MB or HB) generated using the second RAT from the transceiver (e.g., the transceiver 420). The transmission signal may be input to the first PA 962 through a designated transmission fin (e.g., MHB #2 Tx1). The first PA 922 may amplify the transmission signal based on a designated amplification gain based on a power (e.g., ET_1) provided from the power supply 450 (e.g., power supply #1 602 or the power supply module 702), and then transfer the amplified signal to the transmit switch 964.

The transmit switch 964 may perform a switching operation so that a signal transferred from the first PA 962 is input to a corresponding duplexer (e.g., any one of the duplexers 966a, 966b, and 966c). In an embodiment, when MHB module #2 960 may support a total of three bands of a first band, a second band, and a third band, the transmit switch 964 may transfer a signal corresponding to the first band to the first duplexer 966a, transfer a signal corresponding to the second band to the second duplexer 966b, and transfer a signal corresponding to the third band to the third duplexer 966c. In the transmission mode, any one of the first duplexer 966a, the second duplexer 966b, or the third duplexer 966c may transfer a signal input from the transmit switch 964 to the antenna switch 968. The first duplexer 966a, the second duplexer 966b, and the third duplexer 966c may be configured to perform band pass filtering (BPF) on the received signals based on corresponding bands (e.g., the first band, the second band, and the third band).

In an embodiment, the antenna switch 968 may transfer any one of a signal input from the first duplexer 966a, a signal input from the second duplexer 966b, or a signal input from the third duplexer 966c to the third antenna (ANT #3) 970 to be wirelessly transmitted by the third antenna (ANT #3) 970. In an embodiment, a coupler CPL may be connected to a front end of the third antenna (ANT #3) 970 as necessary.

In an embodiment, a signal (e.g., a reception signal) in a designated frequency band (e.g., MB or HB) received through the third antenna 970 may be input to the antenna switch 968, and the antenna switch 968 may perform a switching operation so that the reception signal received through the third antenna 970 is transferred to any one of the first duplexer 966a, the second duplexer 966b, or the third duplexer 966c. For example, in the reception mode, any one of the first duplexer 966a, the second duplexer 966b, or the third duplexer 966c may transfer a signal transferred from the antenna switch 968 to the receive switch 972.

In an embodiment, the receive switch 972 may transfer a signal input from the first duplexer 966a to the first LNA 974a. The first LNA 974a may perform a low noise amplification operation based on a designated amplification gain on the signal input from the receive switch 972 and then transfer the amplified signal to the transceiver through a designated reception fin (e.g., MHB #2 Rx1). In an embodiment, the receive switch 972 may transfer a signal input from the second duplexer 966b to the second LNA 974b. The second LNA 974b may perform a low noise amplification operation based on a designated amplification gain on the signal input from the receive switch 972, and then transfer the amplified signal to the transceiver through a designated reception fin (e.g., MHB #2 Rx2). In an embodiment, the receive switch 972 may transfer a signal input from the third duplexer 966c to the third LNA 974c. The third LNA 974c may perform a low noise amplification operation based on a designated amplification gain on the signal input from the receive switch 972 and then transfer the amplified signal to the transceiver through a designated reception fin (e.g., MHB #2 Rx3).

In an embodiment, the electronic device 101 may include a further downsized RF circuit structure (e.g., an RFFE) using a converged PA configured to support both frequency bands of 2G communication technology and frequency bands of LTE/NR communication technology. For example, the converged PA may include a decoupling capacitor smaller than about 1 nano farad (nF) to use ET power. However, since the RF signal of 2G communication technology has a higher power level than the RF signal of LTE/NR communication technology, the electronic device 101 may need to use a decoupling capacitor of about 1 μF or more to remove noise at the power end.

Referring to FIG. 9E, a UHB module 980 (e.g., the UHB module 616 or the UHB module 716) may include a PA 982 (e.g., the UHB PA 716a or the UHB PA 716a), a transmit/receive switch (Tx-Rx SW) 984, and/or a band pass filter (BPF) 986.

In an embodiment, in the transmission mode of the second RAT, a UHB module 980 may receive an RF signal (e.g., a transmission signal) in a designated frequency band (e.g., an n77 band or an n78 band) generated using the second RAT from the transceiver (e.g., the transceiver 420). The transmission signal may be input to the PA 982 through a designated transmission fin (e.g., UHB #1 Tx1). The PA 982 may amplify the transmission signal based on a designated amplification gain based on a power (e.g., ET_1) provided from the power supply 450 (e.g., power supply #1 602 or the power supply module 702), and then transfer the amplified signal to the transmit/receive switch 984.

In the transmission mode, the transmit/receive switch 984 may transfer the amplified signal output from the PA 982 to the BPF 986. The BPF 986 may perform band pass filtering on the amplified signal. The signal output from the BPF 986 may be transferred to the fifth antenna (ANT #5) 988 to be wirelessly transferred by the fifth antenna (ANT #5) 988. In an embodiment, a coupler CPL may be connected to a front end of the fifth antenna (ANT #5) 988 as necessary.

In an embodiment, a signal (e.g., a reception signal) in a designated frequency band (e.g., an n77 band or an n78 band) received through the fifth antenna 988 may be input to the transmit/receive switch 984 via the BPF 986. In the reception mode, the transmit/receive switch 984 may perform a switching operation so that the reception signal received through the fifth antenna 988 is transferred to the transceiver. For example, in the reception mode, the reception signal may be transferred to the transceiver through a designated receiving fin (e.g., UHB #1 Rx1).

Embodiments of the disclosure relate to an RF circuit structure that selectively supplies APT power and ET power using a switch for power supply of a converged PA configured to support both frequency bands of 2G communication technology and frequency bands of LTE/NR communication technology. It is possible to downsize the RF circuit structure and save material costs through the above-described RF circuit structure.

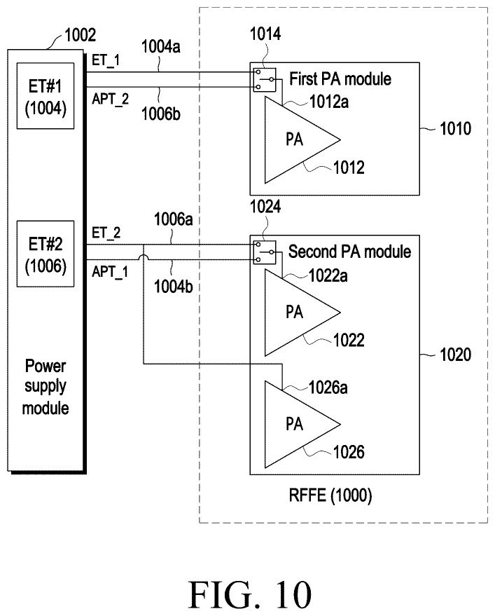

FIG. 10 is a diagram illustrating an example power supply structure including switches for power supply according to various embodiments.

Referring to FIG. 10, a power supply module 1002 may correspond to the power supply 450 of FIG. 4. In an embodiment, the power supply module 1002 may include a first ET modulator 1004 (e.g., the ET modulator 800) and a second ET modulator 1006 (e.g., the ET modulator 800). The RFFE 1000 may correspond to the RFFE 430 of FIG. 4, and may include a first PA 1012, a first switch 1014, a second PA 1022, and a second switch 1024.

In an embodiment, the first PA 1012 and the first switch 1014 may be included in the first PA module 1010 (e.g., LB module #1 1106, LB module #1 1206, or LB module #1 1506) for supporting the designated LB of the first RAT and the designated LB of the second RAT. In an embodiment, the second PA 1022 and the second switch 1024 may be included in the second PA module 1020 (e.g., MHB module #1 1108, MHB module #1 1208, or MHB module #1 1508) for supporting the designated MHB of the first RAT and the designated MHB of the second RAT.

In an embodiment, the first RAT may include at least one of a first wireless communication scheme (e.g., 2G communication technology) or a satellite communication scheme. In an embodiment, the second RAT may include at least one of a second wireless communication scheme (e.g., 4G/LTE communication technology) or a third wireless communication scheme (e.g., 5G/NR communication technology).

In an embodiment, the first ET modulator 1004 may be configured to supply a first ET power ET_1 through a first power line 1004a and/or supply a first APT power APT_1 through a second power line 1004b. In an embodiment, the second ET modulator 1006 may be configured to supply a second ET power ET_2 through a third power line 1006a and/or supply a second APT power A PT_2 through a fourth power line 1006b.

In an embodiment, the first PA 1012 may be configured to amplify RF signals corresponding to the designated LB of the first RAT (e.g., 2G communication technology) and/or the designated LB of the second RAT (e.g., LTE and/or NR communication technology). In an embodiment, the RF signals may include a first transmission signal selected from among a first signal corresponding to a first wireless communication scheme (e.g., 2G communication technology), a second signal corresponding to a second wireless communication scheme (e.g., 4G/LTE communication technology), and a third signal corresponding to a third wireless communication scheme (e.g., 5G/NR communication technology).

In an embodiment, the first switch 1014 may be configured to connect the first PA 1012 to the first ET modulator 1004 or the second ET modulator 1006. In an embodiment, a first input node, a second input node, and a first output node of the first switch 1014 may be connected to the first power line 1004a, the fourth power line 1006b, and the power supply input node 1012a of the first PA 1012, respectively.

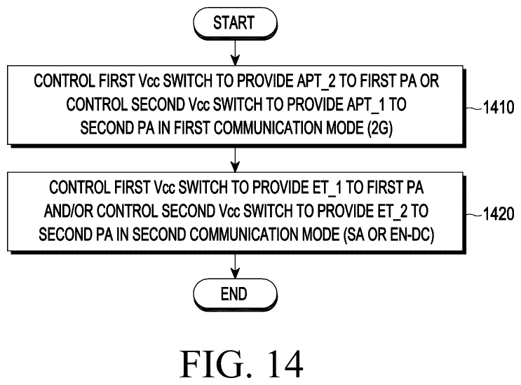

In an embodiment, the first switch 1014 may be configured to select a power provided to the first PA 1012 between ET_1 from the first ET modulator 1004 and APT_2 from the second ET modulator 1006. The first switch 1014 may select either ET_1 or APT_2 under the control of the processor (e.g., the CP 410 or the processor 120) (e.g., the first switching control signal of FIG. 14) and provide it to the first PA 1012. The first PA 1012 may operate based on the power (e.g., ET_1 or APT_2) provided to the power supply input node 1012a through the first switch 1014.

In an embodiment, the second PA 1022 may be configured to amplify RF signals corresponding to the designated MB of the first RAT (e.g., 2G communication technology) and the designated MB of the second RAT (e.g., LTE and/or NR communication technology). In an embodiment, the RF signals may include a second transmission signal selected from among a fourth signal corresponding to the first wireless communication scheme (e.g., 2G communication technology), a fifth signal corresponding to the second wireless communication scheme (e.g., 4G/LTE communication technology), and a sixth signal corresponding to the third wireless communication scheme (e.g., 5G/NR communication technology).

In an embodiment, the second switch 1024 may be configured to electrically connect the second PA 1022 to the first ET modulator 1004 or the second ET modulator 1006. In an embodiment, a third input node, a fourth input node, and a second output node of the second switch 1024 may be connected to the third power line 1006a, the second power line 1004b, and the power supply input node 1022a of the second PA 1022, respectively.

In an embodiment, the second switch 1024 may be configured to select a power provided to the second PA 1022 between ET_2 from the second ET modulator 1006 and APT_1 from the first ET modulator 1004. The second switch 1024 may select either ET_2 or APT_1 under the control of the processor (e.g., the CP 410 or the processor 120) (e.g., the second switching control signal of FIG. 14) and provide it to the second PA 1022. The second PA 1022 may operate based on the power (e.g., ET_2 or APT_1) provided to the power supply input node 1022a through the second switch 1024.

In an embodiment, the second PA module 1020 may further include a third PA 1026 configured to amplify RF signals (e.g., a third transmission signal) corresponding to the designated HB of the first RAT (e.g., 2G communication technology) and the designated HB of the second RAT (e.g., LTE and/or NR communication technology). The third PA 1026 may operate using ET_2 provided through the power supply input node 1026a from the second ET modulator 1006 as a power source. In an embodiment, the first PA 1012 and the second PA 1022 may be a converged PA configured to process both RF signals generated using the first RAT and RF signals generated using the second RAT. In an embodiment, the third PA 1026 may be configured to process RF signals generated using the second RAT, unlike the first PA 1012 and the second PA 1022.

In an alternative embodiment, the first input node, the second input node, and the first output node of the first switch 1014 may be connected to the first power line 1004a, the second power line 1004b, and the power supply input node 1012a of the first PA 1012, respectively, and the first PA 1012 may be operated by any one of ET_1 or APT_1 selected by the first switch 1014. In an embodiment, the third input node, the fourth input node, and the second output node of the second switch 1024 may be connected to the third power line 1006a, the fourth power line 1006b, and the power supply input node 1022a of the second PA 1022, respectively, and the second PA 1022 may be operated by any one of ET_2 or APT_2 selected by the second switch 1024.

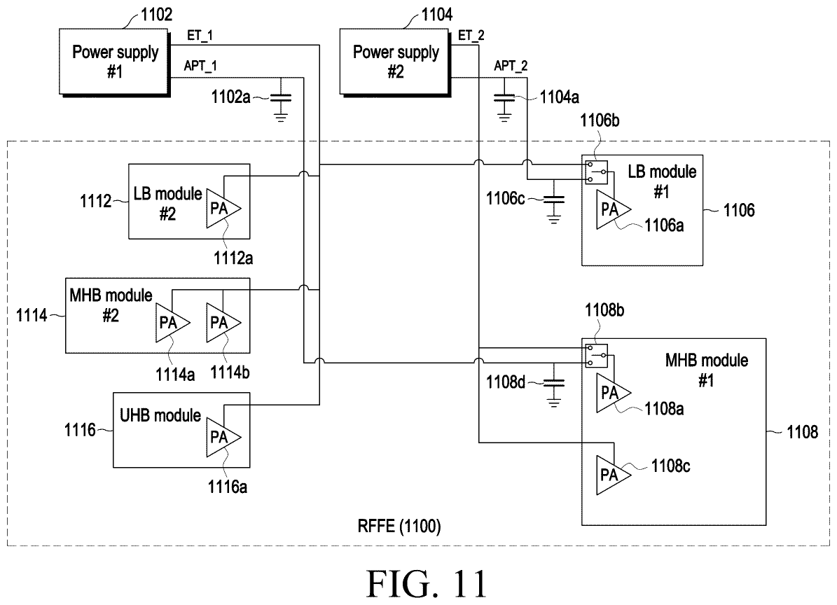

FIG. 11 is a diagram illustrating an example power supply structure including two power supplies according to various embodiments.

Referring to FIG. 11, in an embodiment, power supply #1 1102 may correspond to the first ET modulator 1004 of FIG. 10, and power supply #2 1104 may correspond to the second ET modulator 1006 of FIG. 10. The RFFE 1100 (e.g., the RFFE 1000) may include one or more PA modules (e.g., at least one of LB module #1 1106, MHB module #1 1108, LB module #2 1112, MHB module #2 1114, or at least one UHB module 1116).

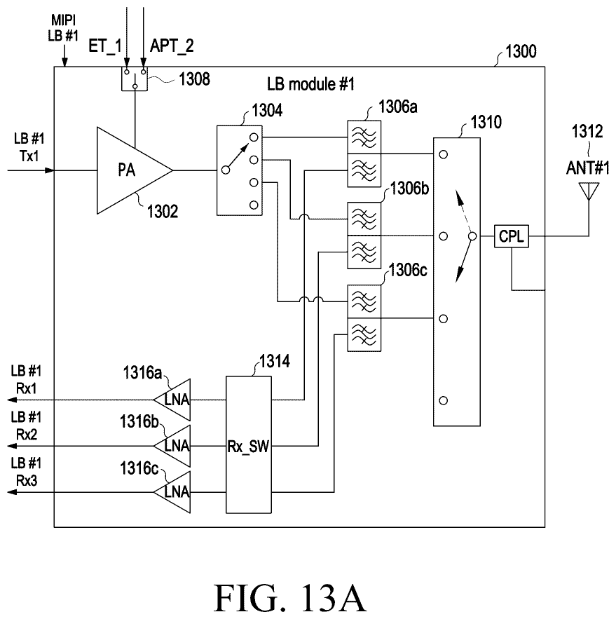

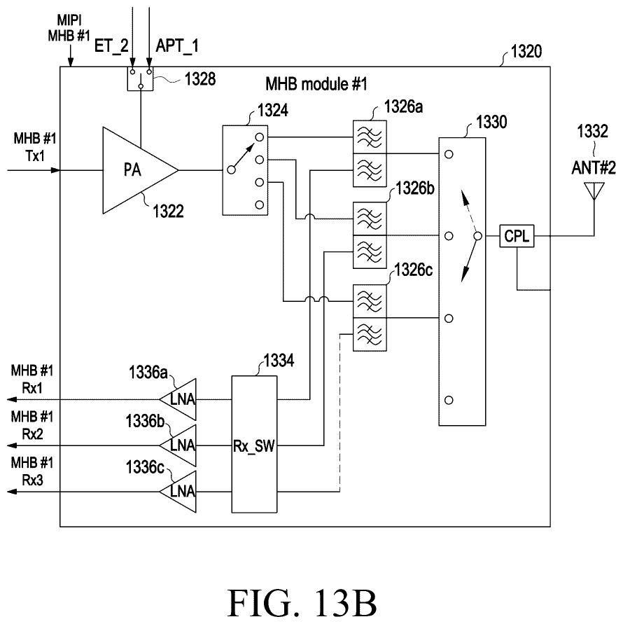

In an embodiment, LB module #1 1106 and/or LB module #2 1112 may be configured to amplify RF signals of a designated LB (e.g., less than about 1 GHz) among RF bands of a first RAT (e.g., 2G communication technology) and/or RF bands of a second RAT (e.g., 4G/LTE communication technology and/or 5G/NR communication technology). In an embodiment, MHB module #1 1108 and/or MHB module #2 1114 may be configured to amplify RF signals of a designated MB (e.g., about 1.4 GHz to 2.3 GHz) and a designated HB (e.g., about 2.3 GHz to 2.7 GHz) among the RF bands of the first RAT and/or the RF bands of the second RAT. In an embodiment, at least one of LB module #1 1106 and MHB module #1 1108 includes an L-PAMiD, and may be responsible for the main path of 2G, 3G, LTE, NR SA, and NR DC. In an embodiment, LB module #1 1106 may be formed to be identical or at least similar to LB module #1 1300 of FIG. 13A. In an embodiment, MHB module #1 1108 may be formed to be identical or at least similar to MHB module #1 1320 of FIG. 13B.

In an embodiment, at least one UHB module 1116 may include at least one UHB PA (e.g., the UHB PA 1116a) configured to amplify RF signals of a designated UHB (e.g., n77 band and/or n78 band) among the RF bands of 5G communication technology.

In an embodiment, each of power supply #1 1102 and power supply #2 1104 may include the ET modulator 800 of FIG. 8. Power supply #1 1102 may be configured to output either the first ET power ET_1 or the first APT power APT_1 through the ET port (e.g., the ET port 810), or the first APT power APT_1 through the APT port (e.g., the APT port 812). Power supply #2 1104 may be configured to output either the second ET power ET_2 or the second APT power APT_2 through the ET port (e.g., the ET port 810), or the second APT power A PT_2 through the APT port (e.g., the APT port 812).

In an embodiment, LB module #1 1106 may include a first LB PA 1106a (e.g., a converged PA or 2G/LTE/NR LB PA) (e.g., the first PA 1012) configured to amplify RF signals (e.g., a first transmission signal) corresponding to the LB of the first RAT and the LB of the second RAT and a switch 1106b (e.g., the first switch 1014) for selecting a power provided to the first LB PA 1106a. The switch 1106d may select any one of ET_1 from power supply #1 1102 and APT_2 from power supply #2 1104 under the control of the processor (e.g., the CP 410 or the processor 120) and provide it to the first LB PA 1106a. The first LB PA 1106a may operate based on power (e.g., ET_1 or APT_2) provided through the switch 1106b. A decoupling capacitor (decap) 1104a (e.g., a capacitor of about 4.7 μF) for removing noise may be connected to the output port of power supply #2 1104 supplying APT_2, and a decoupling capacitor 1106c (e.g., a capacitor of about 1 μF or more) for removing noise may be connected to the input port of LB module #1 1106 receiving APT_2.

In an embodiment, MHB module #1 1108 may include a first MB PA 1108a (e.g., a converged PA or 2G/LTE/NR MB PA) configured to amplify RF signals (e.g., a second transmission signal) corresponding to the MB of the first RAT and the MB of the second RAT, a first HB PA 1108c (e.g., LTE/NR HB PA) configured to amplify RF signals (e.g., a third transmission signal) corresponding to the HB of the second RAT, and a switch 1108b (e.g., the second switch 1024) for selecting a power provided to the first MB PA 1108a. The switch 1108b may select any one of ET_2 from power supply #2 1104 and APT_1 from power supply #1 1102 under the control of the processor (e.g., the CP 410 or the processor 120) and provide it to the first MB PA 1108a. The first MB PA 1108a may operate based on power (e.g., ET_2 or APT_1) provided through the switch 1108b. A decoupling capacitor (decap) 1102a (e.g., a capacitor of about 4.7 μF) for removing noise may be connected to the output port of power supply #1 1102 supplying APT_1, and a decoupling capacitor 1108d (e.g., a capacitor of about 1 μF or more) may be connected to the input port of MHB module #1 1108 receiving APT_1. The first HB PA 1108c may operate based on ET_2 from power supply #2 1102.

In an embodiment, LB module #2 1112 may include a second LB PA 1112a (e.g., PA for LTE/NR LB) configured to amplify RF signals (e.g., a fourth transmission signal) corresponding to the LB of the second RAT. For example, the second LB PA 1112a may operate based on ET_1 from power supply #1 1102. In an embodiment, MHB module #2 1114 may include a second MB PA 1114a (e.g., PA for LTE/NR MB) configured to amplify RF signals (e.g., a fifth transmission signal) corresponding to the MB of the second RAT, and a second HB PA 1114b (e.g., PA for LTE/NR HB) configured to amplify RF signals (e.g., a sixth transmission signal) corresponding to the HB of the second RAT. For example, the second MB PA 1114a and the second HB PA 1114b may operate based on ET_1 from power supply #1 1102.

In an embodiment, at least one UHB module 1116 may include a UHB PA 1116a configured to amplify RF signals (e.g., a seventh transmission signal) of a designated UHB (e.g., n77 band and/or n78 band) among the RF bands of 5G communication technology. For example, the UHB PA 1116a may operate based on ET_1 from power supply #1 1102.

In an embodiment, LB module #2 1112 may be formed to be identical or at least similar to LB module #2 940 of FIG. 9C. In an embodiment, MHB module #2 1114 may be formed to be identical or at least similar to MHB module #2 960 of FIG. 9D. In an embodiment, UHB module #2 1116 may be formed to be identical or at least similar to the UHB module 980 of FIG. 9E.

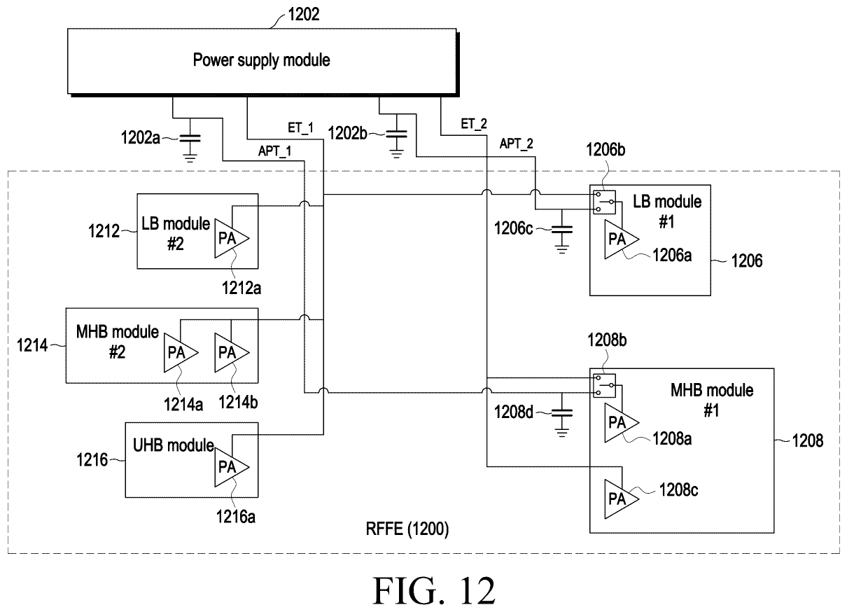

FIG. 12 is a diagram illustrating an example power supply structure including one power supply module according to various embodiments.

Referring to FIG. 12, a power supply module 1202 may correspond to the power supply module 1002 of FIG. 10. In an embodiment, the power supply module 1202 may include the first ET modulator 1004 and the second ET modulator 1006 of FIG. 10. The RFFE 1200 may include one or more PA modules (e.g., at least one of LB module #1 1206, MHB module #1 1208, LB module #2 1212, MHB module #2 1214, or at least one UHB module 1216).

In an embodiment, the power supply module 1202 may include two ET modulators (e.g., the ET modulator 800 of FIG. 8). The power supply module 1202 may be configured to output any one of the first ET power ET_1 and the first APT power APT_1, or to output any one of the second ET power ET_2 and the second APT power APT_1.

In an embodiment, LB module #1 1206 may include a first LB PA 1206a (e.g., a converged PA or 2G/LTE/NR LB PA) (e.g., the first PA 1012) configured to amplify RF signals (e.g., a first transmission signal) corresponding to the LB of the first RAT and the LB of the second RAT and a switch 1206b (e.g., the first switch 1014) for selecting a power provided to the first LB PA 1206a. The switch 1206b may select any one of ET_1 and APT_2 from the power supply module 1202 under the control of the processor (e.g., the CP 410 or the processor 120) and provide it to the first LB PA 1206a. The first LB PA 1206a may operate based on power (e.g., ET_1 or APT_2) provided through the switch 1206b. A decoupling capacitor (decap) 1202b (e.g., a capacitor of about 4.7 μF) for removing noise may be connected to the output port of the power supply module 1202 supplying APT_2, and a decoupling capacitor 1206c (e.g., a capacitor of about 1 μF or more) for removing noise may be connected to the input port of LB module #1 1206 receiving APT_2.

In an embodiment, MHB module #1 1208 may include a first MB PA 1208a (e.g., a converged PA or 2G/LTE/NR MB PA) configured to amplify RF signals (e.g., a second transmission signal) corresponding to the MB of the first RAT and the MB of the second RAT, a first HB PA 1208c (e.g., LTE/NR HB PA) configured to amplify RF signals (e.g., a third transmission signal) corresponding to the HB of the second RAT, and a switch 1208b (e.g., the second switch 1024) for selecting a power provided to the first MB PA 1208a. The switch 1208b may select any one of ET_2 and APT_1 from the power supply module 1202 under the control of the processor (e.g., the CP 410 or the processor 120) and provide it to the first MB PA 1208a. The first MB PA 1208a may operate based on power (e.g., ET_2 or APT_1) provided through the switch 1208b. A decoupling capacitor (decap) 1202a (e.g., a capacitor of about 4.7 μF) for removing noise may be connected to the output port of the power supply module 1202 supplying APT_1, and a decoupling capacitor 1208d (e.g., a capacitor of about 1 μF or more) may be connected to the input port of MHB module #1 1208 receiving APT_1. The first HB PA 1208c may operate based on ET_2 from the power supply module 1202.

In an embodiment, LB module #1 1206 may be formed to be identical or at least similar to LB module #1 1300 of FIG. 13A. In an embodiment, MHB module #1 1208 may be formed to be identical or at least similar to MHB module #1 1320 of FIG. 13B.

In an embodiment, LB module #2 1212 may include a second LB PA 1212a (e.g., PA for LTE/NR LB) configured to amplify RF signals (e.g., a fourth transmission signal) corresponding to the LB of the second RAT. The second LB PA 1212a may operate based on ET_1 from the power supply module 1202. In an embodiment, MHB module #2 1214 may include a second MB PA 1214a (e.g., PA for LTE/NR MB) configured to amplify RF signals (e.g., a fifth transmission signal) corresponding to the MB of the second RAT, and a second HB PA 1214b (e.g., PA for LTE/NR HB) configured to amplify RF signals (e.g., a sixth transmission signal) corresponding to the HB of the second RAT. The second MB PA 1214a and the second HB PA 1214b may operate based on ET_1 from the power supply module 1202.

In an embodiment, at least one UHB module 1216 may include a UHB PA 1216a configured to amplify RF signals (e.g., a seventh transmission signal) of a designated UHB (e.g., n77 band and/or n78 band) among the RF bands of 5G communication technology. The UHB PA 1216a may operate based on ET_1 from the power supply module 1202.

In an embodiment, LB module #2 1212 may be formed to be identical or at least similar to LB module #2 940 of FIG. 9C. In an embodiment, MHB module #2 1214 may be formed to be identical or at least similar to MHB module #2 960 of FIG. 9D. In an embodiment, UHB module #2 1216 may be formed to be identical or at least similar to the UHB module 980 of FIG. 9E.

FIGS. 13A and 13B are diagrams illustrating example structures of PA modules using a switch for power supply according to various embodiments.

Referring to FIG. 13A, LB module #1 1300 (e.g., LB module #1 1106 or LB module #1 1206) may include a PA 1302 (e.g., the first LB PA 1106a or the first LB PA 1106a), a transmit switch (Tx_SW) 1304, a first duplexer 1306a, a second duplexer 1306b, a third duplexer 1306c, an antenna switch (Ant_SW) 1310, a receive switch (Rx_SW) 1314, a first LNA 1316a, a second LNA 1316b, a third LNA 1316c, and/or a switch 1308 (e.g., the switch 1106b or the switch 1206b).

In an embodiment, in the transmission mode of the first RAT (e.g., 2G communication technology) or the second RAT (e.g., LTE and/or NR communication technology), LB module #1 1300 may receive an RF signal (e.g., a transmission signal) in a designated frequency band (e.g., LB) generated using the first RAT or the second RAT from the transceiver (e.g., the transceiver 420). The transmission signal may be input to the PA 1302 through a designated transmission fin (e.g., LB #1 Tx1). The switch 1308 may select any one of two powers (e.g., ET_1 and APT_2) provided from the power supply module 1002 (e.g., power supply #1 1102, power supply #2 1104, or the power supply module 1202) and supply the selected power to the PA 1302. In an embodiment, the switch 1308 may select APT_2 in the communication mode using the first RAT and select ET_1 in the communication mode using the second RAT under the control of the processor (e.g., the CP 410 or the processor 120), but the control operation of the switch 1308 is not limited thereto, and may be performed in various manners according to the frequency band and the communication mode (e.g., SA or EN-DC) performed in the electronic device 101.

In an embodiment, the PA 1302 may be a converged PA configured to amplify the RF signals of both the designated LB of the first RAT and the designated LB of the second RAT. The PA 1302 may amplify the transmission signal based on a designated amplification gain based on the power (e.g., ET_1 or APT_2) provided through the switch 1308, and then transfer the amplified signal to the transmit switch 1304.

The transmit switch 1304 may perform a switching operation so that a signal transferred from the PA 1302 is input to a corresponding duplexer (e.g., any one of the duplexers 1306a, 1306b, and 1306c). In an embodiment, when LB module #1 1300 may support a total of three bands of a first band, a second band, and a third band, the transmit switch 1304 may transfer a signal corresponding to the first band to the first duplexer 1306a, transfer a signal corresponding to the second band to the second duplexer 1306b, and transfer a signal corresponding to the third band to the third duplexer 1306c. The first duplexer 1306a, the second duplexer 1306b, and the third duplexer 1306c may be configured to perform band pass filtering (BPF) on the received signals based on corresponding bands (e.g., the first band, the second band, and the third band).

For example, the signal transferred from the transmit switch 1304 may be input to the first duplexer 1306a, and in the transmission mode, the first duplexer 1306a may filter the signal input from the transmit switch 1304 and then transfer it to the antenna switch 1310. For example, the signal transferred from the transmit switch 1304 may be input to the second duplexer 1306b, and in the transmission mode, the second duplexer 1306b may filter the signal input from the transmit switch 1304 and then transfer it to the antenna switch 1310. For example, the signal transferred from the transmit switch 1304 may be input to the third duplexer 1306c, and in the transmission mode, the third duplexer 1306c may filter the signal input from the transmit switch 1304 and then transfer it to the antenna switch 1310.

In an embodiment, the antenna switch 1310 may transfer any one selected from among a signal input from the first duplexer 1306a, a signal input from the second duplexer 1306b, or a signal input from the third duplexer 1306c to the first antenna (ANT #1) 1312 so that the selected signal is wirelessly transmitted by the first antenna (ANT #1) 1312. In an embodiment, a coupler CPL may be connected to a front end of the first antenna (ANT #1) 1312 as necessary.

In an embodiment, a signal (e.g., a reception signal) in a designated frequency band (e.g., LB) received through the first antenna 1312 may be input to the antenna switch 1310, and the antenna switch 1310 may perform a switching operation so that the reception signal received through the first antenna 1312 is transferred to any one of the first duplexer 1306a, the second duplexer 1306b, or the third duplexer 1306c.

For example, the reception signal transferred from the antenna switch 1310 may be input to the first duplexer 1306a, and in the reception mode of the first RAT or the second RAT, the first duplexer 1306a may filter the reception signal transferred from the antenna switch 1310 and then transfer it to the receive switch 1314. For example, the reception signal transferred from the antenna switch 1310 may be input to the second duplexer 1306b, and in the reception mode of the first RAT or the second RAT, the second duplexer 1306b may filter the signal input from the antenna switch 1310 and then transfer it to the receive switch 1314. For example, the reception signal transferred from the antenna switch 1310 may be input to the third duplexer 1306c, and in the reception mode, the third duplexer 1306c may filter the signal input from the antenna switch 1310 and then transfer it to the receive switch 1314.

In an embodiment, the receive switch 1314 may transfer a signal input from the first duplexer 1306a to the first LNA 1316a. The first LNA 1316a may perform a low noise amplification operation based on a designated amplification gain on the signal input from the receive switch 1314, and then transfer the amplified signal to the transceiver (e.g., the transceiver 420) through a designated reception fin (e.g., LB #1 Rx1). In an embodiment, the receive switch 1314 may transfer a signal input from the second duplexer 1306b to the second LNA 1316b. The second LNA 1316b may perform a low noise amplification operation based on a designated amplification gain on the signal input from the receive switch 1314, and then transfer the amplified signal to the transceiver through a designated reception fin (e.g., LB #1 Rx2). In an embodiment, the receive switch 1314 may transfer a signal input from the third duplexer 1306c to the third LNA 1316c. The third LNA 1316c may perform a low noise amplification operation based on a designated amplification gain on the signal input from the receive switch 1314 and then transfer the amplified signal to the transceiver through a designated reception fin (e.g., LB #1 Rx3).

Referring to FIG. 13B, MHB module #1 1320 (e.g., MHB module #1 1108 or MHB module #1 1208) may include at least one PA 1322 (e.g., the first MB PA 1108a, the first HB PA 1108c, the first MB PA 1208a, or the first HB PA 1208c), a transmit switch (Tx_SW) 1324, a first duplexer 1326a, a second duplexer 1326b, a third duplexer 1326c, an antenna switch (Ant_SW) 1330, a receive switch (Rx_SW) 1334, a first LNA 1336a, a second LNA 1336b, and/or a third LNA 1336c.

In an embodiment, in the transmission mode of the first RAT (e.g., 2G) or the second RAT (e.g., LTE and/or NR communication technology), MHB module #1 1320 may receive an RF signal (e.g., a transmission signal) in a designated frequency band (e.g., MB or LB) generated using the first RAT or the second RAT from the transceiver (e.g., the transceiver 420). The transmission signal may be input to the PA 1322 through a designated transmission fin (e.g., MHB #1 Tx1). The switch 1328 may select any one of two powers (e.g., ET_2 and APT_1) provided from the power supply module 1002 (e.g., power supply #1 1102, power supply #2 1104, or the power supply module 1202) and supply the selected power to the PA 1322. In an embodiment, the switch 1328 may select APT_1 in the communication mode using the first RAT and select ET_2 in the communication mode using the second RAT under the control of the processor (e.g., the CP 410 or the processor 120), but the control operation of the switch 1328 is not limited thereto, and may be performed in various manners according to the frequency band and the communication mode (e.g., SA or EN-DC) performed in the electronic device 101.

The PA 1322 may be a converged PA configured to amplify the RF signals of both the designated MHB of the first RAT and the designated MHB of the second RAT. The PA 1322 may amplify the transmission signal based on a designated amplification gain based on the power (e.g., ET_2 or APT_1) provided through the switch 1328, and then transfer the amplified signal to the transmit switch 1324.

For example, the transmit switch 1324 may perform a switching operation so that a signal transferred from the PA 1322 is input to a corresponding duplexer (e.g., any one of the duplexers 1326a, 1326b, and 1326c). In an embodiment, when MHB module #1 1320 may support a total of three bands of a first band, a second band, and a third band, the transmit switch 1324 may transfer a signal corresponding to the first band to the first duplexer 1326a, transfer a signal corresponding to the second band to the second duplexer 1326b, and transfer a signal corresponding to the third band to the third duplexer 1326c. In the transmission mode, any one of the first duplexer 1326a, the second duplexer 1326b, or the third duplexer 1326c may transfer a signal input from the transmit switch 1324 to the antenna switch 1330. The first duplexer 1326a, the second duplexer 1326b, and the third duplexer 1326c may be configured to perform band pass filtering (BPF) on the received signals based on corresponding bands (e.g., the first band, the second band, and the third band).

In an embodiment, the antenna switch 1330 may transfer any one selected from among a signal input from the first duplexer 1326a, a signal input from the second duplexer 1326b, or a signal input from the third duplexer 1326c to the second antenna (ANT #2) 1332 so that the selected signal is wirelessly transmitted by the second antenna (ANT #2) 1332. In an embodiment, a coupler CPL may be connected to a front end of the second antenna (ANT #2) 1332 as necessary.

In an embodiment, a signal (e.g., a reception signal) in a designated frequency band (e.g., MB or HB) received through the second antenna 1332 may be input to the antenna switch 1330, and the antenna switch 1330 may perform a switching operation so that the reception signal received through the second antenna 1332 is transferred to any one of the first duplexer 1326a, the second duplexer 1326b, or the third duplexer 1326c. For example, in the reception mode, any one of the first duplexer 1326a, the second duplexer 1326b, or the third duplexer 1326c may filter the reception signal transferred from the antenna switch 1330 according to the corresponding band and then transfer it to the receive switch 1334.

In an embodiment, the receive switch 1334 may transfer a signal input from the first duplexer 1326a to the first LNA 1336a. The first LNA 1336a may perform a low noise amplification operation based on a designated amplification gain on the signal input from the receive switch 1334, and then transfer the amplified signal to the transceiver (e.g., the transceiver 420) through a designated reception fin (e.g., MHB #1 Rx1). In an embodiment, the receive switch 1334 may transfer a signal input from the second duplexer 1326b to the second LNA 1336b. The second LNA 1336b may perform a low noise amplification operation based on a designated amplification gain on the signal input from the receive switch 1334, and then transfer the amplified signal to the transceiver through a designated reception fin (e.g., MHB #1 Rx2). In an embodiment, the receive switch 1334 may transfer a signal input from the third duplexer 1326c to the third LNA 1336c. The third LNA 1336c may perform a low noise amplification operation based on a designated amplification gain on the signal input from the receive switch 1334 and then transfer the amplified signal to the transceiver through a designated reception fin (e.g., MHB #1 Rx3).

FIG. 14 is a flowchart illustrating example operations for generating a switching control signal for selecting power for a power amplifier according to various embodiments. At least one of the operations described below may be executed by a processor (e.g., the CP 410 or the processor 120) of the electronic device 101. The operations described below illustrate an example of generating switching control signals that control the switches (e.g., the first switch 1014, the second switch 1024, the switch 1106b, the switch 1108b, the switch 1206b, and/or the switch 1208b) by the processor, and embodiments of the disclosure are not limited thereto.

Referring to FIG. 14, in operation 1410, the processor (e.g., the CP 410 or the processor 120) may generate a first switching control signal for controlling the first switch 1014 (e.g., the switch 1106b or the switch 1206b) to provide APT_2 to the first PA 1012 (e.g., the first LB PA 1106a or the first LB PA 1206a) in the first communication mode using the first RAT (e.g., 2G communication technology) and/or generate a second switching control signal for controlling the second switch 1024 (e.g., the switch 1108b or the switch 1208b) to provide APT_1 to the second PA 1022 (e.g., the first MB PA 1108a or the first MB PA 1208a).

In operation 1420, the processor (e.g., the CP 410 or the processor 120) may generate a first switching control signal for controlling the first switch 1014 (e.g., the switch 1106b or the switch 1206b) to provide ET_1 to the first PA 1012 (e.g., the first LB PA 1106a or the first LB PA 1206a) in the second communication mode (e.g., LTE SA, NR SA, or EN-DC) using the second RAT (e.g., LTE or NR communication technology) and/or generate a second switching control signal for controlling the second switch 1024 (e.g., the switch 1108b or the switch 1208b) to provide ET_2 to the second PA 1022 (e.g., the first MB PA 1108a or the first MB PA 1208a).

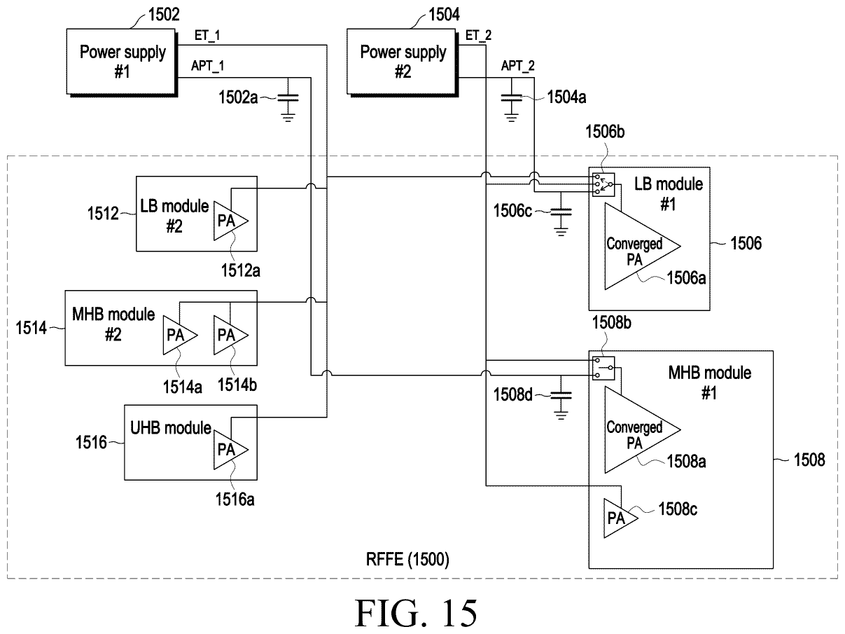

FIG. 15 is a diagram illustrating an example power supply structure including a 3-way switch according to various embodiments.

Referring to FIG. 15, in an embodiment, power supply #1 1502 may correspond to the first ET modulator 1004 of FIG. 10, and power supply #2 1504 may correspond to the second ET modulator 1006 of FIG. 10. The RFFE 1500 (e.g., the RFFE 1000) may include one or more PA modules (e.g., at least one of LB module #1 1506, MHB module #1 1508, LB module #2 1512, MHB module #2 1514, or at least one UHB module 1516).

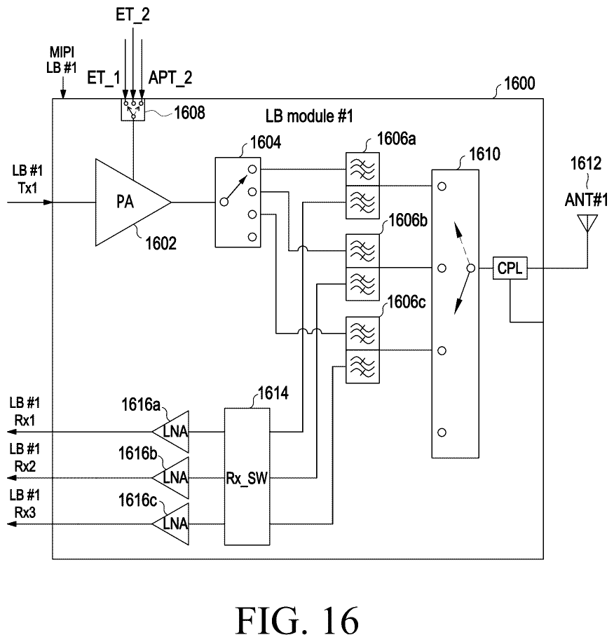

In an embodiment, LB module #1 1506 and/or LB module #2 1512 may be configured to amplify RF signals of a designated LB (e.g., less than about 1 GHz) among RF bands of a first RAT (e.g., 2G communication technology) and/or RF bands of a second RAT (e.g., 4G/LTE communication technology and/or 5G/NR communication technology). In an embodiment, MHB module #1 1508 and/or MHB module #2 1514 may be configured to amplify RF signals of a designated MB (e.g., about 1.4 GHz to 2.3 GHz) and a designated HB (e.g., about 2.3 GHz to 2.7 GHz) among the RF bands of the first RAT and/or the RF bands of the second RAT. In an embodiment, at least one of LB module #1 1506 and MHB module #1 1508 includes an L-PAMiD, and may be responsible for the main path of 2G, 3G, LTE, NR SA, and NR DC. In an embodiment, LB module #1 1506 may be formed to be identical or at least similar to LB module #1 1600 of FIG. 16. In an embodiment, MHB module #1 1508 may be formed to be identical or at least similar to MHB module #1 1320 of FIG. 13B.

In an embodiment, at least one UHB module 1516 may include at least one UHB PA (e.g., the UHB PA 1516a) configured to amplify RF signals of a designated UHB (e.g., n77 band and/or n78 band) among the RF bands of 5G communication technology.

In an embodiment, each of power supply #1 1502 and power supply #2 1504 may include the ET modulator 800 of FIG. 8. Power supply #1 1502 may be configured to output either the first ET power ET_1 or the first APT power APT_1 through the ET port, or the first APT power APT_1 through the APT port. Power supply #2 1504 may be configured to output either the second ET power ET_2 or the second APT power APT_1 through the ET port, or the second APT power APT_2 through the APT port. In an embodiment, power supply #1 1502 and power supply #2 1504 may be replaced with a single power supply module (e.g., the power supply module 1202).

In an embodiment, LB module #1 1506 may include a first LB PA 1506a (e.g., a converged PA or 2G/LTE/NR LB PA) (e.g., the first PA 1012) configured to amplify RF signals (e.g., a first transmission signal) corresponding to the LB of the first RAT and the LB of the second RAT and a switch 1506b (e.g., the first switch 1014) for selecting a power provided to the first LB PA 1506a. In an embodiment, the switch 1506b may include a single pole three through (SP3T) switch. The switch 1506b may select any one of ET_1 from power supply #1 1502, ET_2 from power supply #2 1504, and APT_2 from power supply #2 1504 under the control of the processor (e.g., the CP 410 or the processor 120) and provide it to the first LB PA 1506a. In an embodiment, the first LB PA 1506a may operate based on power (e.g., ET_1, ET_2, or APT_2) provided through the switch 1506b. A decoupling capacitor (decap) 1504a (e.g., a capacitor of about 4.7 μF) for removing noise may be connected to the output port of power supply #2 1504 supplying APT_2, and a decoupling capacitor 1506c (e.g., a capacitor of about 1 μF or more) for removing noise may be connected to the input port of LB module #1 1506 receiving APT_2.

In an embodiment, MHB module #1 1508 may include a first MB PA 1508a (e.g., a converged PA or 2G/LTE/NR MB PA) configured to amplify RF signals (e.g., a second transmission signal) corresponding to the MB of the first RAT and the MB of the second RAT, a first HB PA 1508c (e.g., LTE/NR HB PA) configured to amplify RF signals (e.g., a third transmission signal) corresponding to the HB of the second RAT, and a switch 1508b (e.g., the second switch 1024) for selecting a power provided to the first MB PA 1508a. The switch 1508b may select any one of ET_2 from power supply #2 1504 and APT_1 from power supply #1 1502 under the control of the processor (e.g., the CP 410 or the processor 120) and provide it to the first MB PA 1508a. The first MB PA 1508a may operate based on power (e.g., ET_2 or APT_1) provided through the switch 1508b. A decoupling capacitor (decap) 1502a (e.g., a capacitor of about 4.7 μF) for removing noise may be connected to the output port of power supply #1 1502 supplying APT_1, and a decoupling capacitor 1508d (e.g., a capacitor of about 1 μF or more) may be connected to the input port of MHB module #1 1508 receiving APT_1. For example, the first HB PA 1508c may operate based on ET_2 from power supply #2 1502.

In an embodiment, LB module #2 1512 may include a second LB PA 1512a (e.g., PA for LTE/NR LB) configured to amplify RF signals (e.g., a fourth transmission signal) corresponding to the LB of the second RAT. The first LB PA 1512a may operate based on ET_1 from power supply #2 1502. In an embodiment, MHB module #2 1514 may include a second MB PA 1514a (e.g., PA for LTE/NR MB) configured to amplify RF signals (e.g., a fifth transmission signal) corresponding to the MB of the second RAT, and a second HB PA 1514b (e.g., PA for LTE/NR HB) configured to amplify RF signals (e.g., a sixth transmission signal) corresponding to the HB of the second RAT. The second MB PA 1514a and the second HB PA 1514b may operate based on ET_1 from power supply #1 1502.

In an embodiment, at least one UHB module 1516 may include a UHB PA 1516a configured to amplify RF signals (e.g., a seventh transmission signal) of a designated UHB (e.g., n77 band and/or n78 band) among the RF bands of 5G communication technology. The UHB PA 1516a may operate based on ET_1 from power supply #1 1502.

In an embodiment, LB module #2 1512 may be formed to be identical or at least similar to LB module #2 940 of FIG. 9C. In an embodiment, MHB module #2 1514 may be formed to be identical or at least similar to MHB module #2 960 of FIG. 9D. In an embodiment, UHB module #2 1516 may be formed to be identical or at least similar to the UHB module 980 of FIG. 9E.

The power supply structure of FIG. 15, as compared to the power supply structure of FIG. 11 or FIG. 12, allows the first LB PA 1506a to selectively use any one of the two ET power supplies in the communication mode of SA or EN-DC through the three-way switch 1506b. In an embodiment, the processor (e.g., the CP410 or the processor 120) may control the switch 1506b to supply ET_2 to the first LB PA 1506a of LB module #1 1506 in the communication mode of EN-DC, thereby enabling dual-connection of EN-DC through both LB module #1 1506 using ET_2 and LB module #2 1512 using ET_1.

FIG. 16 is a diagram illustrating an example structure of a PA module using a 3-way switch according to various embodiments.

Referring to FIG. 16, LB module #1 1600 (e.g., LB module #1 1506) may include a PA 1602 (e.g., the first LB PA 1506a), a transmit switch (Tx_SW) 1604, a first duplexer 1606a, a second duplexer 1606b, a third duplexer 1606c, an antenna switch (Ant_SW) 1610, a receive switch (Rx_SW) 1614, a first LNA 1616a, a second LNA 1616b, a third LNA 1616c, and/or a switch 1608 (e.g., the switch 1506b).

In an embodiment, in the transmission mode of the first RAT (e.g., 2G communication technology) or the second RAT (e.g., LTE and/or NR communication technology), LB module #1 1600 may receive an RF signal (e.g., a transmission signal) in a designated frequency band (e.g., LB) generated using the second RAT from the transceiver (e.g., the transceiver 420). The transmission signal may be input to the PA 1602 through a designated transmission fin (e.g., LB #1 Tx1). The switch 1608 may select any one of three powers (e.g., ET_1, ET_2, and A PT_2) provided from the power supply module 1002 (e.g., power supply #1 1502, power supply #2 1504, or the power supply module 1202) and supply the selected power to the PA 1602. In an embodiment, the switch 1608 may select APT_2 in the communication mode using the first RAT and select ET_1 or ET_2 in the communication mode using the second RAT under the control of the processor (e.g., the CP 410 or the processor 120), but the control operation of the switch 1608 is not limited thereto, and may be performed in various manners according to the frequency band and the communication mode (e.g., SA or EN-DC) performed in the electronic device 101.

The PA 1602 may be a converged PA configured to amplify the RF signals of both the designated LB of the first RAT and the designated LB of the second RAT. The PA 1602 may amplify the transmission signal based on a designated amplification gain based on the power (e.g., ET_1, ET_2, or APT_2) provided through the switch 1608, and then transfer the amplified signal to the transmit switch 1604.

The transmit switch 1604 may perform a switching operation so that a signal transferred from the PA 1602 is input to a corresponding duplexer (e.g., any one of the duplexers 1606a, 1606b, and 1606c). In an embodiment, when LB module #1 1600 may support a total of three bands of a first band, a second band, and a third band, the transmit switch 1604 may transfer a signal corresponding to the first band to the first duplexer 1606a, transfer a signal corresponding to the second band to the second duplexer 1606b, and transfer a signal corresponding to the third band to the third duplexer 1606c. The first duplexer 1606a, the second duplexer 1606b, and the third duplexer 1606c may be configured to perform band pass filtering (BPF) on the received signals based on corresponding bands (e.g., the first band, the second band, and the third band).

For example, the signal transferred from the transmit switch 1604 may be input to the first duplexer 1606a, and in the transmission mode, the first duplexer 1606a may filter the signal input from the transmit switch 1604 and then transfer it to the antenna switch 1610. For example, the signal transferred from the transmit switch 1604 may be input to the second duplexer 1606b, and in the transmission mode, the second duplexer 1606b may filter the signal input from the transmit switch 1604 and then transfer it to the antenna switch 1610. For example, the signal transferred from the transmit switch 1604 may be input to the third duplexer 1606c, and in the transmission mode, the third duplexer 1606c may filter the signal input from the transmit switch 1604 and then transfer it to the antenna switch 1610.

In an embodiment, the antenna switch 1610 may transfer any one selected from among a signal input from the first duplexer 1606a, a signal input from the second duplexer 1606b, or a signal input from the third duplexer 1606c to the first antenna (ANT #1) 1612 so that the selected signal is wirelessly transmitted by the first antenna (ANT #1) 1612. In an embodiment, a coupler CPL may be connected to a front end of the first antenna (ANT #1) 1612 as necessary.

In an embodiment, a signal (e.g., a reception signal) in a designated frequency band (e.g., LB) received through the first antenna 1612 may be input to the antenna switch 1610, and the antenna switch 1610 may perform a switching operation so that the reception signal received through the first antenna 1612 is transferred to any one of the first duplexer 1606a, the second duplexer 1606b, or the third duplexer 1606c.

For example, the reception signal transferred from the antenna switch 1610 may be input to the first duplexer 1606a, and in the reception mode of the first RAT or the second RAT, the first duplexer 1606a may filter the reception signal transferred from the antenna switch 1610 and then transfer it to the receive switch 1614. For example, the reception signal transferred from the antenna switch 1610 may be input to the second duplexer 1606b, and in the reception mode of the first RAT or the second RAT, the second duplexer 1606b may filter the signal input from the antenna switch 1610 and then transfer it to the receive switch 1614. For example, the reception signal transferred from the antenna switch 1610 may be input to the third duplexer 1606c, and in the reception mode, the third duplexer 1606c may filter the signal input from the antenna switch 1610 and then transfer it to the receive switch 1614.

In an embodiment, the receive switch 1614 may transfer a signal input from the first duplexer 1606a to the first LNA 1616a. The first LNA 1616a may perform a low noise amplification operation based on a designated amplification gain on the signal input from the receive switch 1614, and then transfer the amplified signal to the transceiver (e.g., the transceiver 420) through a designated reception fin (e.g., LB #1 Rx1). In an embodiment, the receive switch 1614 may transfer a signal input from the second duplexer 1606b to the second LNA 1616b. The second LNA 1616b may perform a low noise amplification operation based on a designated amplification gain on the signal input from the receive switch 1614, and then transfer the amplified signal to the transceiver through a designated reception fin (e.g., LB #1 Rx2). In an embodiment, the receive switch 1614 may transfer a signal input from the third duplexer 1606c to the third LNA 1616c. The third LNA 1616c may perform a low noise amplification operation based on a designated amplification gain on the signal input from the receive switch 1614 and then transfer the amplified signal to the transceiver through a designated reception fin (e.g., LB #1 Rx3).

Embodiments of the disclosure may reduce the number of required ET modulators (e.g., the first ET modulator 1004 and the second ET modulator 1006) using at least one switch (e.g., the switch 1014 and/or the switch 1024) and enable use of a converged PA (e.g., the PA 1012 and the PA 1022) supporting both ET power and APT power. Embodiments of the disclosure may enhance PA efficiency using ET power, reduce the mounting area, and save material costs.

Wireless communication circuitry for use in an electronic device according to an example embodiment may comprise: a power amplifier (PA) configured to amplify radio frequency (RF) signals in a first frequency band of a first radio access technology (RAT) in a first communication mode and to amplify RF signals in a second frequency band of a second RAT in a second communication mode; a switch including a first input node configured to be connectable to receive an envelope tracking ET power supply signal, a second input node configured to be connectable to receive an average power tracking APT power supply signal, and an output node connected to the PA, and configured to switchably connect one of the first input node and the second input node to the output node in response to a switching control signal.

In an example embodiment, in the first communication mode, the wireless communication circuitry may be configured to input the switching control signal corresponding to a first switching signal to the switch to select the ET power supply signal to be provided to the PA. In an example embodiment, in the second communication mode, the switching control signal corresponding to a second switching signal may be input to the switch to select the APT power supply signal to be provided to the PA.

In an example embodiment, the first frequency band may include a first RF band related to the APT power supply signal for RF amplification. In an example embodiment, the second frequency band may include a second RF band related to the ET power supply signal for RF amplification.

In an example embodiment, the first RAT may comprise at least one of 2nd generation (2G) communication technology or a satellite communication technology. In an example embodiment, the second RAT may comprise at least one of 4th generation (4G) communication technology, long-term evolution (LTE) communication technology, 5th generation (5G) communication technology, or new radio (NR) communication technology.

In an example embodiment, the ET power supply signal and the APT power supply signal may be generated by different power supply modules, respectively.

An electronic device according to an example embodiment of the disclosure may comprise: a first power supply configured to generate a first electrical power by an envelope tracking (ET) power supply scheme and a second electrical power by an average power tracking (APT) power supply scheme; a second power supply configured to generate a third electrical power by the ET power supply scheme and a fourth electrical power by the APT power supply scheme; a first power amplifier (PA) configured to amplify RF signals in a first frequency band of a first radio access technology RAT and a second frequency band of a second RAT; a first switch including a first input node configured to be connectable to receive the first electrical power, a second input node configured to be connectable to receive the fourth electrical power, and a first output node connected to the first PA, wherein the first switch may be configured to switchably connect one of the first input node and the second input node to the first output node, in response to a first switching control signal for selecting, based on a communication mode of the electronic device, one of the first electrical power and the fourth electrical power and providing the selected one to the first PA via the first output node.

In an example embodiment, the electronic device may comprise: a second PA configured to amplify RF signals in a third frequency band of the first RAT and a fourth frequency band of the second RAT; and a second switch including a third input node configured to be connectable to receive the third electrical power, a fourth input node configured to be connectable to receive the second electrical power, and a second output node connected to the second PA, wherein the second switch may be configured to switchably connect one of the third input node and the fourth input node to the second output node in response to a second switching control signal for selecting, based on the communication mode of the electronic device, one of the third electrical power and the second electrical power and providing the selected on to the second PA via the second output node.

In an example embodiment, the first power supply may include a first ET modulator, and the first ET modulator may comprise an ET port configured to output either the first electrical power or the second electrical power, and an APT port configured to output the second electrical power. In an example embodiment, the second power supply may comprise: a second ET modulator, and the second ET modulator may comprise an ET port configured to output either the third electrical power or the fourth electrical power, and an APT port configured to output the fourth electrical power.

In an example embodiment, the first RAT may comprise: at least one of a 2nd generation (2G) communication technology or a satellite communication technology. In an example embodiment, the second RAT may comprise at least one of 4G communication technology, LTE communication technology, 5G communication technology, or NR communication technology.

In an example embodiment, the electronic device may comprise: memory storing instructions, at least one processor, comprising processing circuitry, operatively connected to the memory, and individually and/or collectively, configured to cause the electronic device to: provide the first switching control signal and the second switching control signal based on the communication mode of the electronic device, and a transceiver configured to generate at least one RF transmit signal using the first RAT or the second RAT based on the communication mode, and output the at least one RF transmit signal to at least one of the first PA or the second PA; based on the electronic device operating in a first communication mode using the 2G communication technology, control the first switch to connect the fourth electrical power to the first PA, or control the second switch to connect the second electrical power to the second PA, and based on the electronic device operating in a standalone (SA) communication mode using NR communication technology or in an evolved universal mobile telecommunications system terrestrial radio access (E-UTRA) NR dual connectivity (EN-DC) communication mode, control the first switch to connect the first electrical power to the first PA, and/or control the second switch to connect the third electrical power to the second PA.

In an example embodiment, the electronic device may comprise: a first decoupling capacitor connected to the second input node of the first switch and configured to remove noise of the fourth electrical power, the first decoupling capacitor having a capacitance of 1 μF or more and a second decoupling capacitor connected to the fourth input node of the second switch and configured to remove noise of the second electrical power, the second decoupling capacitor having a capacitance of 1 μF or more.

In an example embodiment, at least one of the first frequency band of the first RAT or the second frequency band of the second RAT may include a frequency band of less than 1 GHz. In an example embodiment, at least one of the third frequency band of the first RAT or the fourth frequency band of the second RAT may include a frequency band from 1 GHz to 2.3 GHz and a frequency band from 2.3 GHz to 2.7 GHz.

An electronic device according to an example embodiment of the disclosure may comprise: a first envelope tracking modulator configured to selectively provide a first envelope tracking (ET) power via a first power line, or a first average power tracking (APT) power via a second power line; a second envelope tracking modulator configured to selectively supply a second ET power via a third power line, or a second APT power via a fourth power line; a first amplifier configured to amplify a first transmission signal selected from among a first signal corresponding to a first wireless communication scheme, a second signal corresponding to a second wireless communication scheme, and a third signal corresponding to a third wireless communication scheme; a second amplifier configured to amplify a second transmission signal selected from among a fourth signal corresponding to the first wireless communication scheme, a fifth signal corresponding to the second wireless communication scheme, and a sixth signal corresponding to the third wireless communication scheme. The fourth signal may correspond to a higher frequency band than the first signal, the fifth signal may correspond to a higher frequency band than the second signal, and the sixth signal may correspond to a higher frequency band than the third signal. The electronic device may comprise: a first switch configured to connect the first amplifier to the first envelope tracking modulator or the second envelope tracking modulator; and a second switch configured to connect the second amplifier to the first envelope tracking modulator or the second envelope tracking modulator.

In an example embodiment, a first input node, a second input node, and a first output node of the first switch may be connected to the first power line, the fourth power line, and a power supply input node of the first amplifier, respectively. In an example embodiment, a third input node, a fourth input node, and a second output node of the second switch may be connected to the third power line, the second power line, and a power supply input node of the second amplifier, respectively.

In an example embodiment, the first switch further may include a fifth input node, and the fifth input node may be connected to the third power line.

In an example embodiment, a first input node, a second input node, and a first output node of the first switch may be connected to the first power line, the second power line, and a power supply input node of the first amplifier, respectively. In an example embodiment, a third input node, a fourth input node, and a second output node of the second switch may be connected to the third power line, the fourth power line, and a power supply input node of the second amplifier, respectively.

In an example embodiment, the electronic device may further comprise: a third amplifier configured to amplify a third transmission signal selected from among a seventh signal corresponding to the second wireless communication scheme and an eighth signal corresponding to the third wireless communication scheme, and connected to the third power line. The seventh signal may correspond to a higher frequency band than the fifth signal, and the eighth signal may correspond to a higher frequency band than the sixth signal.

In an example embodiment, the second amplifier and the third amplifier may be configured to be connected in parallel with each other with respect to the third power line.

In an example embodiment, the electronic device may further comprise: a fourth amplifier configured to amplify a fourth transmission signal selected from among a ninth signal corresponding to the second wireless communication scheme and a tenth signal corresponding to the third wireless communication scheme, and connected to the first power line.

In an example embodiment, the ninth signal may correspond to the same frequency band as the second signal, and the tenth signal may correspond to the same frequency band as the third signal.

In an example embodiment, the electronic device may further comprise: a fifth amplifier configured to amplify a fifth transmission signal selected from among an eleventh signal corresponding to the second wireless communication scheme and a twelfth signal corresponding to the third wireless communication scheme and connected to the first power line, and a sixth amplifier configured to amplify a sixth transmission signal selected from among a thirteenth signal corresponding to the second cellular communication scheme and a fourteenth signal corresponding to the third cellular communication scheme, and connected to the first power line.

In an example embodiment, the thirteenth signal may correspond to a higher frequency band than the eleventh signal, and the fourteenth signal may correspond to a higher frequency band than the twelfth signal.

In an example embodiment, the fifth amplifier and the sixth amplifier may be configured to be connected in parallel with each other with respect to the first power line.

In an example embodiment, the electronic device may further comprise a seventh amplifier configured to amplify a seventh transmission signal which is a fifteenth signal corresponding to the third wireless communication scheme, and connected to the first power line.

The electronic device according to various embodiments of the disclosure may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used herein, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., memory 390, internal memory 136 or external memory 138) that is readable by a machine (e.g., the electronic device 101). For example, a processor (e.g., the processor 310 or processor 120) of the machine (e.g., the electronic device 202 or 204 or electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The storage medium readable by the machine may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smartphones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. Wireless communication circuitry configured for use in an electronic device comprising:
a power amplifier (PA) configured to amplify RF signals in a first frequency band of a first radio access technology (RAT) in a first communication mode and to amplify RF signals in a second frequency band of a second RAT in a second communication mode; and
a switch including a first input node configured to be connectable to receive an envelope tracking (ET) power supply signal, a second input node configured to be connectable to receive an average power tracking (APT) power supply signal, and an output node connected to the PA, and configured to switchably connect one of the first input node and the second input node to the output node in response to a switching control signal.

2. The wireless communication circuitry of claim 1, wherein in the first communication mode, the wireless communication circuitry is configured to input the switching control signal corresponding to a first switching signal to the switch to select the ET power supply signal to be provided to the PA, and
in the second communication mode, the wireless communication circuitry is configured to input the switching control signal corresponding to a second switching signal to the switch to select the APT power supply signal to be provided to the PA.

3. The wireless communication circuitry of claim 1, wherein the first frequency band includes a first RF band related to the APT power supply signal for RF amplification, and
wherein the second frequency band includes a second RF band related to the ET power supply signal for RF amplification.

4. The wireless communication circuitry of claim 1, wherein the first RAT comprises at least one of 2nd generation (2G) communication technology or a satellite communication technology, and
wherein the second RAT comprises at least one of 4th generation (4G) communication technology, long-term evolution (LTE) communication technology, 5th generation (5G) communication technology, or new radio (NR) communication technology.

5. The wireless communication circuitry of claim 1,
wherein the ET power supply signal and the APT power supply signal are configured to be generated by different power supply modules, respectively.

6. An electronic device comprising:
a first power supply configured to generate a first electrical power by an envelope tracking (ET) power supply scheme and a second electrical power by an average power tracking (APT) power supply scheme;
a second power supply configured to generate a third electrical power by the ET power supply scheme and a fourth electrical power by the APT power supply scheme;
a first power amplifier (PA) configured to amplify RF signals in a first frequency band of a first radio access technology (RAT) and a second frequency band of a second RAT; and
a first switch including a first input node configured to be connectable to receive the first electrical power, a second input node configured to be connectable to receive the fourth electrical power, and a first output node connected to the first PA,
wherein the first switch is configured to switchably connect one of the first input node and the second input node to the first output node, in response to a first switching control signal for selecting, based on a communication mode of the electronic device, one of the first electrical power and the fourth electrical power and providing the selected one to the first PA via the first output node.

7. The electronic device of claim 6, comprising:
a second PA configured to amplify RF signals in a third frequency band of the first RAT and a fourth frequency band of the second RAT; and
a second switch including a third input node configured to be connectable to receive the third electrical power, a fourth input node configured to be connectable to receive the second electrical power, and a second output node connected to the second PA,
wherein the second switch is configured to switchably connect one of the third input node and the fourth input node to the second output node in response to a second switching control signal for selecting, based on the communication mode of the electronic device, one of the third electrical power and the second electrical power and providing the selected on to the second PA via the second output node.

8. The electronic device of claim 7, wherein the first power supply includes a first ET modulator, wherein the first ET modulator comprises an ET port configured to output either the first electrical power or the second electrical power, and an APT port configured to output the second electrical power, and
wherein the second power supply comprises a second ET modulator, and wherein the second ET modulator comprises an ET port configured to output either the third electrical power or the fourth electrical power, and an APT port configured to output the fourth electrical power.

9. The electronic device of claim 7, wherein the first RAT comprises at least one of a 2nd generation (2G) communication technology or a satellite communication technology, and
wherein the second RAT comprises at least one of 4th generation (4G) communication technology, long-term evolution (LTE) communication technology, 5th generation (5G) communication technology, or new radio (NR) communication technology.

10. The electronic device of claim 9, comprising
memory storing instructions;
at least one processor, comprising processing circuitry, operatively connected to the memory, and individually and/or collectively, configured to cause the electronic device to: provide the first switching control signal and the second switching control signal based on the communication mode of the electronic device; and
a transceiver configured to generate at least one RF transmit signal using the first RAT or the second RAT based on the communication mode, and to output the at least one RF transmit signal to at least one of the first PA or the second PA,
wherein the instructions, when executed by the at least one processor, individually and/or collectively, cause the electronic device to:
based on the electronic device operating in a first communication mode using the 2G communication technology, control the first switch to connect the fourth electrical power to the first PA, or control the second switch to connect the second electrical power to the second PA, and
based on the electronic device operating in a standalone (SA) communication mode using the NR communication technology or in an EN-DC (evolved universal mobile telecommunications system terrestrial radio access (E-UTRA) NR dual connectivity) communication mode, control the first switch to connect the first electrical power to the first PA, and/or control the second switch to connect the third electrical power to the second PA.

11. The electronic device of claim 7, comprising:
a first decoupling capacitor connected to the second input node of the first switch and configured to remove noise of the fourth electrical power, the first decoupling capacitor having a capacitance of 1 μF or more; and
a second decoupling capacitor connected to the fourth input node of the second switch and configured to remove noise of the second electrical power, the second decoupling capacitor having a capacitance of 1 μF or more.

12. The electronic device of claim 6,
wherein at least one of the first frequency band of the first RAT or the second frequency band of the second RAT includes a frequency band of less than 1 GHz,
wherein at least one of the third frequency band of the first RAT or the fourth frequency band of the second RAT includes a frequency band from 1 GHz to 2.3 GHz and a frequency band from 2.3 GHz to 2.7 GHz.

13. An electronic device comprising:
a first envelope tracking modulator configured to selectively provide a first envelope tracking (ET) power via a first power line, or a first average power tracking (APT) power via a second power line;
a second envelope tracking modulator configured to selectively supply a second ET power via a third power line, or a second APT power via a fourth power line;
a first amplifier configured to amplify a first transmission signal selected from among a first signal corresponding to a first wireless communication scheme, a second signal corresponding to a second wireless communication scheme, and a third signal corresponding to a third wireless communication scheme;
a second amplifier configured to amplify a second transmission signal selected from among a fourth signal corresponding to the first wireless communication scheme, a fifth signal corresponding to the second wireless communication scheme, and a sixth signal corresponding to the third wireless communication scheme, wherein the fourth signal corresponds to a higher frequency band than the first signal, the fifth signal corresponds to a higher frequency band than the second signal, and the sixth signal corresponds to a higher frequency band than the third signal;
a first switch configured to connect the first amplifier to the first envelope tracking modulator or the second envelope tracking modulator; and
a second switch configured to connect the second amplifier to the first envelope tracking modulator or the second envelope tracking modulator.

14. The electronic device of claim 13,
wherein a first input node, a second input node, and a first output node of the first switch are connected to the first power line, the fourth power line, and a power supply input node of the first amplifier, respectively,
wherein a third input node, a fourth input node, and a second output node of the second switch are connected to the third power line, the second power line, and a power supply input node of the second amplifier, respectively.

15. The electronic device of claim 14, wherein the first switch further includes a fifth input node, and the fifth input node is connected to the third power line.

16. The electronic device of claim 13,
wherein a first input node, a second input node, and a first output node of the first switch are connected to the first power line, the second power line, and a power supply input node of the first amplifier, respectively, and
wherein a third input node, a fourth input node, and a second output node of the second switch are connected to the third power line, the fourth power line, and a power supply input node of the second amplifier, respectively.

17. The electronic device of claim 13, further comprising: a third amplifier configured to amplify a third transmission signal selected from among a seventh signal corresponding to the second wireless communication scheme and an eighth signal corresponding to the third wireless communication scheme, and connected to the third power line,
wherein the seventh signal corresponds to a higher frequency band than the fifth signal, and the eighth signal may correspond to a higher frequency band than the sixth signal, and
wherein the second amplifier and the third amplifier are configured to be connected in parallel with each other with respect to the third power line.

18. The electronic device of claim 13, further comprising: a fourth amplifier configured to amplify a fourth transmission signal selected from among a ninth signal corresponding to the second wireless communication scheme and a tenth signal corresponding to the third wireless communication scheme, and connected to the first power line,
wherein the ninth signal corresponds to the same frequency band as the second signal, and the tenth signal may correspond to the same frequency band as the third signal.

19. The electronic device of claim 13, further comprising:
a fifth amplifier configured to amplify a fifth transmission signal selected from among an eleventh signal corresponding to the second wireless communication scheme and a twelfth signal corresponding to the third wireless communication scheme and connected to the first power line, and
a sixth amplifier configured to amplify a sixth transmission signal selected from among a thirteenth signal corresponding to the second cellular communication scheme and a fourteenth signal corresponding to the third cellular communication scheme, and connected to the first power line.
wherein the thirteenth signal corresponds to a higher frequency band than the eleventh signal, and the fourteenth signal may correspond to a higher frequency band than the twelfth signal, and
wherein the fifth amplifier and the sixth amplifier are configured to be connected in parallel with each other with respect to the first power line.

20. The electronic device of claim 19, further comprising a seventh amplifier configured to amplify a seventh transmission signal which is a fifteenth signal corresponding to the third wireless communication scheme, and connected to the first power line.
